(19) United States
(12) Patent Application Publication
(10) Pub. No.: US 2026/0271531 A1
(43) Pub. Date: Sep. 10, 2026

(54) DISPLAY DEVICE, ELECTRONIC DEVICE, AND METHOD OF MANUFACTURING THE DISPLAY DEVICE

(71) Applicant: Samsung Display Co., Ltd., Yongin-Si (KR)

(72) Inventors: Sung Hoon MOON, Yongin-si (KR); Sung Jun KIM, Yongin-si (KR); Dong Hyeok LEE, Yongin-si (KR); Moo Soon KO, Yongin-si (KR); Yong Ho YANG, Yongin-si (KR); Young In HWANG, Yongin-si (KR); Do Hoon KIM, Yongin-si (KR); Jin Seock MA, Yongin-si (KR)

(21) Appl. No.: 19/331,141

(22) Filed: Sep. 17, 2025

(30) Foreign Application Priority Data
Mar. 4, 2025 (KR) 10-2025-0027539

(51) Int. Cl. H10K 59/122; H10K 59/12; H10K 59/121

(52) U.S. Cl. CPC H10K 59/122; H10K 59/1201; H10K 59/1213

(57) ABSTRACT

A display device according to an embodiment includes a substrate, a circuit layer located on the substrate and including transistors and an organic layer at least partially covering the transistors, a light emitting element layer located on the organic layer and including light emitting elements located in emission areas and a pixel defining layer located in a non-emission area between the emission areas, and a separation structure formed in the organic layer and the pixel defining layer in the non-emission area, wherein the separation structure includes an opening penetrating one of the organic layer and the pixel defining layer, and a groove overlapping the opening and recessed into a surface of another one of the organic layer and the pixel defining layer.

### CROSS-REFERENCE TO RELATED APPLICATION

This application claims the benefit of Korean Patent Application No. 10-2025-0027539, filed on Mar. 4, 2025, in the Korean Intellectual Property Office, the disclosure of which is incorporated herein in its entirety by reference.

### BACKGROUND

### 1. Field

Embodiments of the present disclosure relate to a display device, an electronic device and a method of manufacturing the display device.

### 2. Description of the Related Art

As the information society develops, demands for display devices and electronic devices, which can display images, are increasing in various forms. Accordingly, various types of display devices and electronic devices, which include pixels for displaying images, are being developed. The display devices may be provided alone or may be included in the electronic devices and used as display screens of the electronic devices.

### SUMMARY

Aspects of the present disclosure provide a display device and an electronic device which can reduce leakage current and a method of manufacturing the display device.

However, aspects of the present disclosure are not restricted to the one set forth above. The above and other aspects of the present disclosure will become more apparent to one of ordinary skill in the art to which the present disclosure pertains by referencing the detailed description of the present disclosure given below.

According to an embodiment of the present disclosure, a display device includes a substrate, a circuit layer located on the substrate and including transistors and an organic layer at least partially covering the transistors, a light emitting element layer located on the organic layer and including light emitting elements located in emission areas and a pixel defining layer located in a non-emission area between the emission areas, and a separation structure formed in the organic layer and the pixel defining layer in the non-emission area, wherein the separation structure includes an opening penetrating one of the organic layer and the pixel defining layer, and a groove overlapping the opening and recessed into a surface of another one of the organic layer and the pixel defining layer.

In an embodiment, a sidewall of the groove may include an inclined surface and a slope of the inclined surface is greater than a slope of a sidewall of the opening.

In an embodiment, the sidewall of the groove may have a slope of 70 degrees or more.

In an embodiment, each of the light emitting elements may include a first electrode located in each of the emission areas, at least one light emitting layer and intermediate layers located on the first electrode, and a second electrode located on the at least one light emitting layer and the intermediate layers, the intermediate layers may be located over a display area including the emission areas and the non-emission area, and at least one of the intermediate layers may be broken or separated in an area where the groove is located.

In an embodiment, in a width direction of the separation structure, a sidewall of the opening and a sidewall of the groove may be located at positions spaced apart from each other.

In an embodiment, the groove may have a smaller width than the opening.

In an embodiment, in the width direction of the separation structure, the groove may be located in a center of the opening.

In an embodiment, the emission areas may include a first emission area and a second emission area extending in a first direction and adjacent to each other in a second direction, and the separation structure may be located between the first emission area and the second emission area and may extend in the first direction.

In an embodiment, the display device may further include a plurality of separation structures which include the separation structure, and the plurality of separation structures may be distributed between the emission areas.

In an embodiment, the display device may further include spacers located on the pixel defining layer and spaced apart from the separation structures.

In an embodiment, each of the organic layer and the pixel defining layer may include an organic insulating material.

In an embodiment, the circuit layer may further include a conductive pattern located under the separation structure, and the conductive pattern may be covered with one of the organic layer and the pixel defining layer.

In an embodiment, the circuit layer may further include a conductive pattern located under the organic layer and not overlapping the separation structure.

In an embodiment, the pixel defining layer may further include an additional groove recessed into a surface at a position overlapping the conductive pattern.

According to an embodiment of the present disclosure, an electronic device includes a display module including a display panel, and a processor to transmit an image data signal to the display module, wherein the display panel includes a substrate, a circuit layer located on the substrate and including transistors and an organic layer at least partially covering the transistors, a light emitting element layer located on the organic layer and including light emitting elements located in emission areas and a pixel defining layer located in a non-emission area between the emission areas, and a separation structure formed in the organic layer and the pixel defining layer in the non-emission area, wherein the separation structure includes an opening penetrating one of the organic layer and the pixel defining layer, and a groove overlapping the opening and recessed into a surface of another one of the organic layer and the pixel defining layer.

In an embodiment, a sidewall of the groove may include an inclined surface and a slope of the inclined surface is greater than a slope of a sidewall of the opening.

In an embodiment, in a width direction of the separation structure, a sidewall of the opening and a sidewall of the groove may be located at positions spaced apart from each other.

According to an embodiment of the present disclosure, a method of manufacturing a display device includes sequentially forming transistors and an organic layer, which at least partially covers the transistors, on a substrate, forming first electrodes of light emitting elements on the organic layer, forming a pixel defining layer, which defines emission areas where the first electrodes of the light emitting elements are exposed and is located in a non-emission area surrounding the emission areas, on the organic layer, and forming light emitting layers, intermediate layers and a second electrode of the light emitting elements on the first electrodes of the light emitting elements and the pixel defining layer, wherein an opening is formed in one of the organic layer and the pixel defining layer in the non-emission area and a groove is formed in another one of the organic layer and the pixel defining layer to overlap the opening, before the forming of the light emitting layers, the intermediate layers and the second electrode.

In an embodiment, the intermediate layers and the second electrode may be formed over the entire display area including the emission areas and the non-emission area.

In an embodiment, the groove may be formed to include a sidewall and a slope of the sidewall is greater than a slope of a sidewall of the opening, and at least one of the intermediate layers may be broken or separated in an area where the groove is located.

According to a display device, an electronic device, and a method of manufacturing the display device according to embodiments, an opening is formed in one of a pixel defining layer and an organic layer under the pixel defining layer. Therefore, deterioration of the display device and the electronic device can be improved. At the same time, a groove having a relatively large lateral slope is formed in the other one of the pixel defining layer and the organic layer. Therefore, leakage current of the display device and the electronic device can be reduced or blocked. In addition, according to the display device, the electronic device, and the method of manufacturing the display device according to the embodiments, the opening and the groove of the pixel defining layer and the organic layer are placed to overlap each other. Therefore, the leakage current of the display device and the electronic device can be improved more effectively.

However, effects according to the embodiments of the present disclosure are not limited to those exemplified above and various other effects are incorporated herein.

### BRIEF DESCRIPTION OF THE DRAWINGS

These and other aspects will become apparent and more readily appreciated from the following description of the embodiments, taken in conjunction with the accompanying drawings in which:

FIG. 1 is a perspective view illustrating a display device and an electronic device according to an embodiment;

FIG. 2 is a perspective view of a display panel according to an embodiment;

FIG. 3 is a plan view of a portion of a display area according to an embodiment;

FIG. 4 is a cross-sectional view of a portion of the display panel according to the embodiment;

FIG. 5 is a detailed cross-sectional view of area A1 of FIG. 4;

FIG. 6 is a cross-sectional view of a portion of a display panel according to an embodiment;

FIG. 7 is a detailed cross-sectional view of area A2 of FIG. 6;

FIG. 8 is a cross-sectional view of a portion of a display panel according to an embodiment;

FIG. 9 is a cross-sectional view of a portion of a display panel according to an embodiment;

FIGS. 10, 11, 12, 13, and 14 are cross-sectional views illustrating a method of manufacturing a display device according to an embodiment;

FIGS. 15, 16, 17, 18, 19, and 20 are cross-sectional views illustrating a method of manufacturing a display device according to an embodiment;

FIG. 21 is a block diagram of an electronic device according to an embodiment; and

FIG. 22 is a schematic diagram of electronic devices according to various embodiments.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

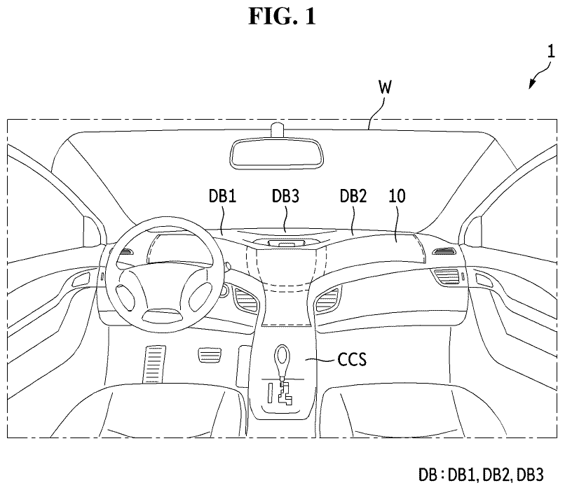

FIG. 1 is a perspective view illustrating a display device 10 and an electronic device 1 according to an embodiment.

Referring to FIG. 1, the electronic device 1 according to the embodiment may provide a display screen on which an image is displayed. For example, the electronic device 1 may be a television, a notebook computer, a monitor, a billboard, an Internet of things (IoT) device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game console, a digital camera, a camcorder or an automobile, which provides a display screen. In FIG. 1, an automobile is shown as an example of the electronic device 1 which includes the display screen.

The electronic device 1 may include the display device 10 (or a display module) which includes a display screen. The display device 10 is a device that displays a moving image or a still image. The display device 10 may be included in various types and sizes of electronic devices 1 and used as a display screen. Examples of the display device 10 may include an inorganic light emitting diode display device, an organic light emitting display device, a quantum dot light emitting display device, a plasma display panel, and a field emission display device. The display device 10 according to the embodiment may be, but is not limited to, an organic light emitting diode display device including an organic light emitting diode.

The shape of the electronic device 1 can be variously changed. For example, as illustrated in FIG. 1, when the electronic device 1 is an automobile, it may include a windshield W, a dashboard DB, and a center console CCS. The shapes of the windshield W, the dashboard DB, and the center console CCS of the electronic device 1 can be variously changed according to the shape of the automobile body.

The windshield W may be a transparent structure located in front of a driver's seat and a passenger seat. The windshield W may protect the driver and passengers from external elements while the automobile is being driven.

The dashboard DB may provide various information about a vehicle infotainment system to the driver and other passengers. The vehicle infotainment system refers to a system that provides information and entertainment to the driver and other passengers by integrating in-vehicle and external systems. The vehicle infotainment system may include devices or technologies that provide, inside a vehicle, Internet browsing, movies, games, television services, social networking services (SNS), and various services linked to a navigation device and a mobile device.

The dashboard DB may include a first dashboard DB1 located in front of the driver's seat, a second dashboard DB2 located in front of the passenger seat, and a third dashboard DB3 located between the first dashboard DB1 and the second dashboard DB2.

In an embodiment, the first dashboard DB1 may include an instrument panel and the like to provide the driver with various information necessary for driving, such as speed information and automobile status information. For example, the first dashboard DB1 may include a digital cluster.

In an embodiment, the third dashboard DB3 may provide map information, music information, temperature information, etc. The third dashboard DB3 may provide various functions which can operate convenience functions that assist in driving the automobile. For example, the third dashboard DB3 may include a center information display (CID).

In an embodiment, the second dashboard DB2 may provide the above information of the first dashboard DB1 and the third dashboard DB3 to a passenger in the passenger seat. For example, the second dashboard DB2 may include a co-driver display.

The center console CCS may be located below the third dashboard DB3. The center console CCS may be located between the driver's seat and the passenger seat. In an embodiment, the center console CCS may include various functional members for controlling the way the automobile is driven, such as a gear lever, a parking brake, and a driving mode button. In the drawing, an analog method in which the gear lever, etc. are operated by physical manipulation is illustrated as an example. However, embodiments are not limited to this method. For example, since the display device 10 includes an input device such as a touch panel, a digital operating method through operation buttons, etc. displayed on the display device 10 may also be used.

The information provided on each of the dashboard DB and the center console CCS is not necessarily provided only on any one of the dashboard DB and the center console CCS. The information provided on any one of the dashboard DB and the center console CCS may also be provided on the other one of the dashboard DB and the center console CCS.

The electronic device 1 according to the embodiment may provide various information to a user through the display device 10 or may operate other elements included in the electronic device 1 based on information input by the user through the display device 10.

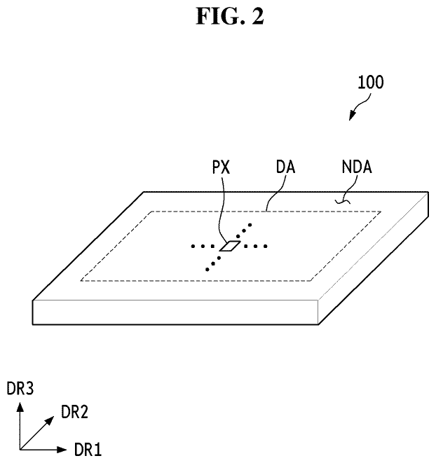

FIG. 2 is a perspective view of a display panel 100 according to an embodiment. For example, FIG. 2 shows an example of a display panel 100 that can be included in the display device 10 and the electronic device 1 according to the embodiment.

Referring to FIGS. 1 and 2, the display device 10 and the electronic device 1 according to the embodiment may include the display panel 100 that forms a display screen. For example, the display panel 100 may be included in a display module of the display device 10 or a display module of the electronic device 1 and may display an image corresponding to input data.

The electronic device 1 and the display device 10 according to the embodiment may further include a driving circuit for controlling the operation of the display panel 100. The driving circuit may include a scan driver and a data driver which generate driving signals of the display panel 100, a timing controller which controls the operation of the scan driver and the data driver, and a power supply unit which generates driving voltages of the display panel 100. Each of the scan driver, the data driver, the timing controller and the power supply unit may be formed inside the display panel 100 together with pixels PX or may be placed on a surface of the display panel 100 or on a circuit board electrically connected to the display panel 100 and may be electrically connected to the display panel 100.

The shape of the display panel 100 can be variously changed. For example, the display panel 100 may have a shape corresponding to that of the display screen of the electronic device 1 and the display device 10. The display panel 100 may have a substantially flat shape or may have a shape which includes a curved surface in at least one part. In addition, the display panel 100 may be formed to have rigid properties so that it is not easily deformed or may be formed to have flexible properties so that it can be easily deformed.

In an embodiment, the display panel 100 may have a rectangular shape in a plane as illustrated in FIG. 2. For example, the display panel 100 may have a rectangular shape in a plane defined by a first direction DR1 and a second direction DR2. For example, the display panel 100 may include two long sides extending in the first direction DR1 and two short sides extending in the second direction DR2 intersecting the first direction DR1. Each corner where a long side and a short side of the display panel 100 meet may be right-angled. However, embodiments are not limited to this case, and each corner may also include a curved surface. For example, each corner portion of the display panel 100 may be angled or rounded. The display panel 100 may have a thickness in a third direction DR3 intersecting the first direction DR1 and the second direction DR2. The third direction DR3 may be, but is not limited to, a direction perpendicular to a plane defined by the first direction DR1 and the second direction DR2. For example, the first direction DR1 and the second direction DR2 may be a horizontal direction and a vertical direction of the display panel 100, respectively, and the third direction DR3 may be a thickness direction of the display panel 100.

The shape of the display panel 100 is not limited to the shape shown in FIG. 2. For example, the display panel 100 included in the display device 10 of FIG. 1 may have a shape corresponding to that of the display screen of the display device 10. For example, when the display device 10 is integrally placed on the dashboard DB and the center console CCS of the electronic device 1 as illustrated in FIG. 1, the display panel 100 may have a shape corresponding to the shapes of the dashboard DB and the center console CCS.

In FIGS. 1 and 2, the display panel 100 and the display device 10 are distinguished from each other, and the display panel 100 is described as a part of the display device 10, but embodiments are not limited to this case. For example, when the display device 10 refers to an element that forms the display screen of the electronic device 1, the display panel 100 may mean the display device 10. For example, the display panel 100 may mean a main element that is included in the display device 10 (or the electronic device 1) to form a screen or may mean the display device 10 itself.

The display panel 100 may include a display area DA and a non-display area NDA. The display area DA may be an area where an image is displayed, and the non-display area NDA may be an area where an image is not displayed.

The pixels PX may be located in the display area DA. An image corresponding to input data may be displayed in the display area DA by the pixels PX.

The non-display area NDA may be located around the display area DA. For example, the non-display area NDA may be located in an edge portion of the display panel 100 and may surround the display area DA.

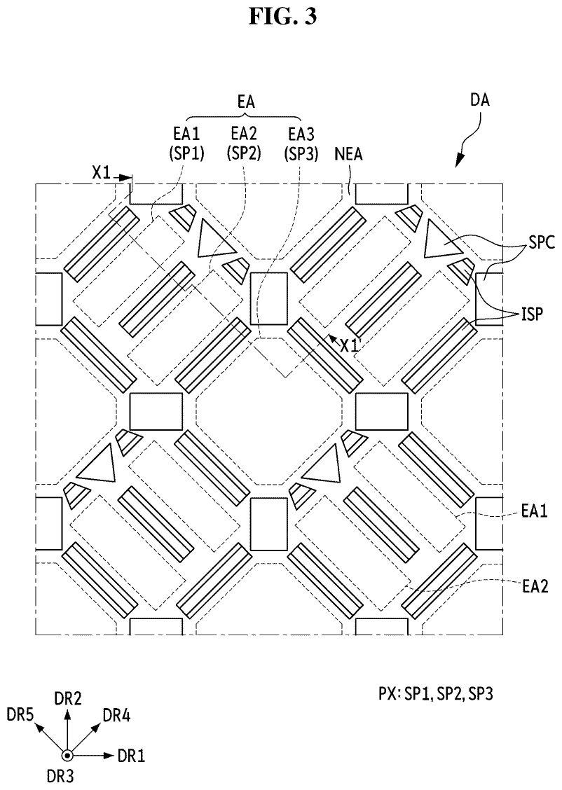

FIG. 3 is a plan view of a portion of a display area DA according to an embodiment. For example, FIG. 3 shows a portion of the display area DA of the display panel 100 (or the display device 10) according to the embodiment.

Referring to FIGS. 1 through 3, pixels PX for displaying an image may be arranged in the display area DA of the display panel 100. Each pixel PX may include a plurality of emission areas EA. For example, each pixel PX may include a first emission area EA1, a second emission area EA2, and a third emission area EA3.

In an embodiment, each pixel PX may include a plurality of subpixels (e.g., a first subpixel SP1, a second subpixel SP2, and a third subpixel SP3) which can be driven independently of each other. Each subpixel may include a light emitting element and circuit elements for controlling the light emitting element. For example, each subpixel may include a light emitting element which emits light of a specific color and circuit elements which are electrically connected to the light emitting element and control a driving current flowing through the light emitting element in response to a scan signal and a data signal transmitted from the scan driver and the data driver, respectively. The circuit elements may include transistors, which include a driving transistor and a switching transistor, and a capacitor for storing a data signal.

Each subpixel may include an emission area EA. The emission area EA may be an area where light generated by each subpixel is emitted to the outside. For example, the emission area EA of each subpixel may be an area where a light emitting element of the corresponding subpixel is located and may be a light-transmitting area through which light generated by the light emitting element can pass.

Specifically, the first subpixel SP1 may include the first emission area EA1 in which a light emitting element of the first subpixel SP1 is located, and light generated by the light emitting element is emitted. The second subpixel SP2 may include the second emission area EA2 in which a light emitting element of the second subpixel SP2 is located, and light generated by the light emitting element is emitted. The third subpixel SP3 may include the third emission area EA3 in which a light emitting element of the third subpixel SP3 is located, and light generated by the light emitting element is emitted.

In an embodiment, the first subpixel SP1, the second subpixel SP2, and the third subpixel SP3 may emit light of different colors. For example, the first emission area EA1, the second emission area EA2, and the third emission area EA3 may emit light of a first color, light of a second color, and light of a third color, respectively. In an embodiment, the light of the first color, the light of the second color, and the light of the third color may be red light, green light, and blue light, respectively. For example, the light of the first color may be light in a red wavelength band of about 600 to 750 nm, the light of the second color may be light in a green wavelength band of about 480 to 560 nm, and the light of the third color may be light in a blue wavelength band of about 370 to 460 nm, but embodiments are not limited to this example. In addition, the color or wavelength band of light emitted from each subpixel (or each emission area EA) can be variously changed according to embodiments.

In an embodiment, each pixel PX may include one first subpixel SP1, one second subpixel SP2, and one third subpixel SP3. In this case, each pixel PX may include one first emission area EA1, one second emission area EA2, and one third emission area EA3. A plurality of emission areas EA included in each pixel PX may be located adjacent to each other.

However, embodiments are not limited to the above case. For example, each pixel PX may also include two first emission areas EA1, two second emission areas EA2, and one third emission area EA3 located adjacent to each other. In addition, the number, ratio, or arrangement structure of subpixels or emission areas EA that constitute each pixel PX can be variously changed according to embodiments.

Each of the first emission area EA1, the second emission area EA2, and the third emission area EA3 may have a planar shape such as a rectangle, a square, or a rhombus. For example, as illustrated in FIG. 3, the first emission area EA1 and the second emission area EA2 may have a rectangular shape, and the third emission area EA3 may have a square or rhombus shape with chamfered vertices. However, embodiments are not limited to this example, and the shape of each of the first emission area EA1, the second emission area EA2 and the third emission area EA3 may also be changed to various shapes such as a circle, an ellipse, and other polygons.

In an embodiment, the first emission area EA1, the second emission area EA2, and the third emission area EA3 included in one pixel PX may neighbor each other in a fourth direction DR4 or a fifth direction DR5. For example, a plurality of emission areas EA included in one pixel PX may be sequentially arranged in the fourth direction DR4 or the fifth direction DR5, and the arrangement order or arrangement form of the emission areas EA may vary depending on embodiments. In the drawing, the fourth direction DR4 may be a diagonal direction between the first direction DR1 and the second direction DR2. For example, the fourth direction DR4 may form an angle of 45 degrees with respect to each of the first direction DR1 and the second direction DR2, but embodiments not limited to this example. The fifth direction DR5 may be a diagonal direction between an opposite direction of the first direction DR1 and the second direction DR2. For example, the fifth direction DR5 may form an angle of 90 degrees with respect to the fourth direction DR4, but embodiments are not limited to this example.

In an embodiment, first and second emission areas EA1 and EA2 of a first type, which extend in the fourth direction DR4, and first and second emission areas EA1 and EA2 of a second type, which extend in the fifth direction DR5, may coexist in the display area DA. The first and second emission areas EA1 and EA2 of the first type and the first and second emission areas EA1 and EA2 of the second type may be arranged alternately in the first direction DR1 or the second direction DR2. For example, in the first direction DR1, the first and second emission areas EA1 and EA2 of the first type or the first and second emission areas EA1 and EA2 of the second type may be arranged sequentially or continuously. In the second direction DR2, the first and second emission areas EA1 and EA2 of the first type and the first and second emission areas EA1 and EA2 of the second type may be arranged alternately. The third emission areas EA3 may be arranged sequentially or continuously in the first direction DR1 and the second direction DR2. The third emission areas EA3 may be located between the first and second emission areas EA1 and EA2 of the first type and the first and second emission areas EA1 and EA2 of the second type in each of the fourth direction DR4 and the fifth direction DR5.

In an embodiment, when one pixel PX includes one first emission area EA1 and one second emission area EA2, the first emission area EA1 and the second emission area EA2 included in the pixel PX may extend in the same direction. For example, one pixel PX may include a first emission area EA1 of the first type and a second emission area EA2 of the first type which extend in the fourth direction DR4 or may include a first emission area EA1 of the second type and a second emission area EA2 of the second type which extend in the fifth direction DR5.

In an embodiment, when one pixel PX includes two first emission areas EA1, the two first emission areas EA1 included in the pixel PX may extend in different directions. For example, one of the two first emission areas EA1 included in the pixel PX may be a first emission area EA1 of the first type which extends in the fourth direction DR4, and the other may be a first emission area EA1 of the second type which extends in the fifth direction DR5. Similarly, when one pixel PX includes two second emission areas EA2, the two second emission areas EA2 included in the pixel PX may extend in different directions. For example, one of the two second emission areas EA2 included in the pixel PX may be a second emission area EA2 of the first type which extends in the fourth direction DR4, and the other may be a second emission area EA2 of the second type which extends in the fifth direction DR5.

In an embodiment, sizes or areas of the first emission area EA1, the second emission area EA2, and the third emission area EA3 may be different from each other. For example, the size or area of one second emission area EA2 may be larger than the size or area of one first emission area EA1 and smaller than the size or area of one third emission area EA3. For example, in the fourth direction DR4 or the fifth direction DR5, the first emission area EA1 may have a smaller width than each of the second emission area EA2 and the third emission area EA3, and the third emission area EA3 may have a greater width than each of the first emission area EA1 and the second emission area EA2. In an embodiment, in a length direction intersecting a width direction of each emission area EA, lengths of the first emission area EA1, the second emission area EA2, and the third emission area EA3 may be substantially equal, but embodiments are not limited to this case.

FIG. 3 only shows an embodiment related to the arrangement form of the emission areas EA, and embodiments are not limited to this embodiment. For example, the shape, size and number of emission areas EA arranged in the display area DA, or the arrangement structure of the emission areas EA can be variously changed according to embodiments.

The display area DA may further include a non-emission area NEA surrounding the emission areas EA. The non-emission area NEA may surround each of the emission areas EA and may be located between the emission areas EA. The emission areas EA may be spaced apart from each other by a portion of the non-emission area NEA. The portion of the non-emission area NEA may be located between the emission areas EA.

The display panel 100 may further include spacers SPC and separation structures ISP located in the non-emission area NEA of the display area DA. The spacers SPC and the separation structures ISP may not spatially overlap each other. For example, when viewed in a plane (e.g., an XY plane) defined by the first direction DR1 and the second direction DR2, the spacers SPC and the separation structures ISP may be spaced apart from each other. In addition, the spacers SPC and the separation structures ISP may be relatively evenly distributed in the non-emission area NEA throughout the display area DA. For example, the display panel 100 may include a plurality of spacers SPC and a plurality of separation structures ISP evenly distributed in the non-emission area NEA.

The spacers SPC may be located on a portion of a pixel defining layer which defines the emission areas EA. The spacers SPC may prevent interference between the subpixels or the pixels PX and may act as a buffer to protect the display panel 100.

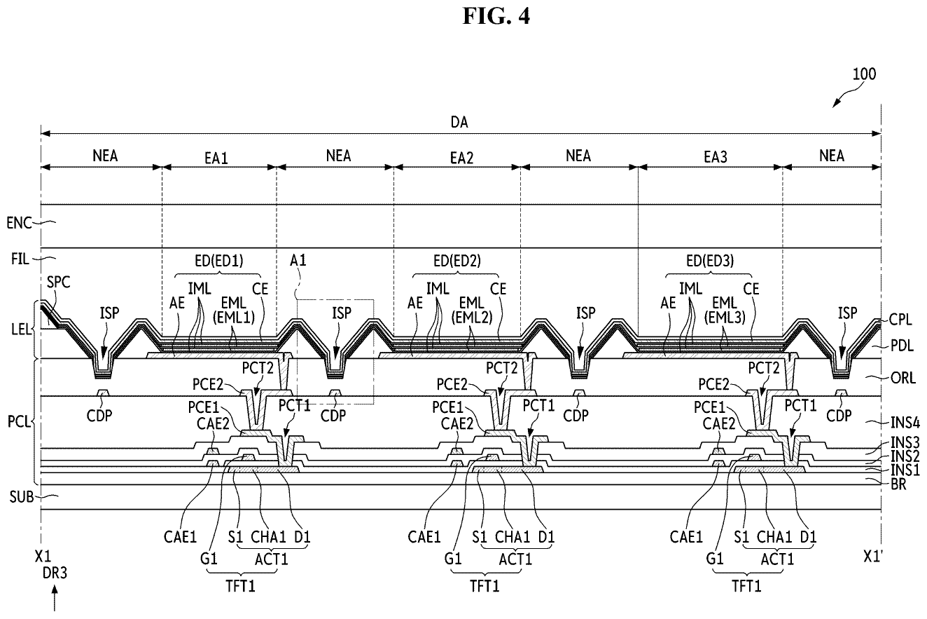

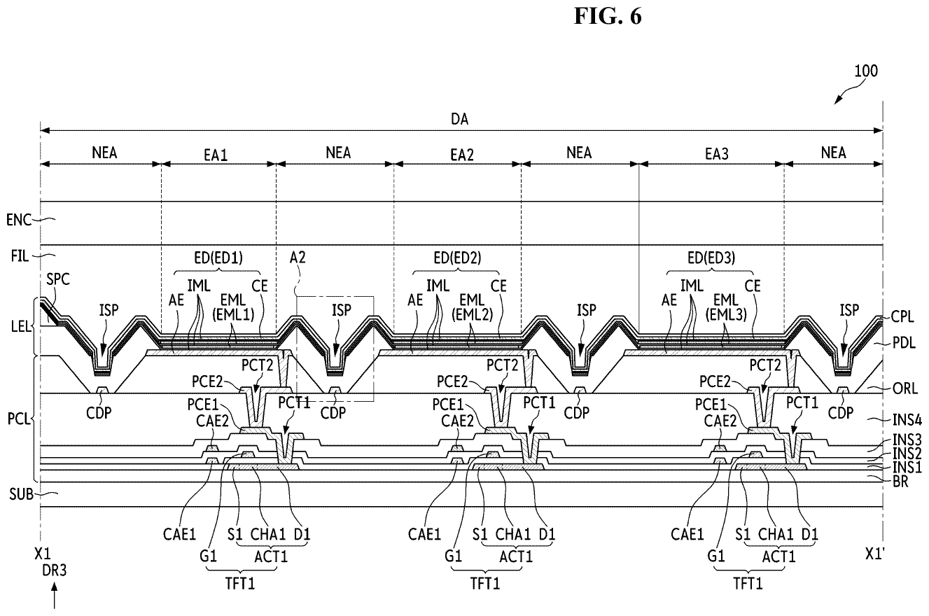

Each of the separation structures ISP may be located between adjacent emission areas EA or spacers SPC. Each of the separation structures ISP may include an opening which penetrates one of a pixel defining layer (e.g., a pixel defining layer PDL of FIG. 4 or 6) and an organic layer (e.g., an organic layer ORL of FIG. 4 or 6) under the pixel defining layer and a groove which is formed in a surface of the other one of the pixel defining layer and the organic layer. The groove may spatially overlap the opening. For example, in each separation structure ISP, the groove may be located inside an area where the opening is formed (e.g., in a central portion of the area where the opening is formed). Accordingly, each separation structure ISP may be formed as an integrated separator including the opening and the groove which are formed to overlap organic insulating layers sequentially or continuously stacked in the display panel 100.

Each of the spacers SPC and the separation structures ISP may be sized and shaped not to intrude into surrounding emission areas EA or other structures. In an embodiment, each of the separation structures ISP may have a shape and width that match a shape and width of the non-emission area NEA.

For example, a separation structure ISP located between a pair of the first emission area EA1 and the second emission area EA2, which extend in the fourth direction DR4 and are adjacent to each other in the fifth direction DR5, may extend in the fourth direction DR4 and may have a width smaller than a width of the non-emission area NEA in the fifth direction DR5 (e.g., a width corresponding to a distance between the pair of the first emission area EA1 and the second emission area EA2). In this case, a groove included in the separation structure ISP may be shaped like a trench extending in the fourth direction DR4 and having a width smaller than the width of the non-emission area NEA in the fifth direction DR5 (e.g., a trench having a rectangular planar shape and extending in the fourth direction DR4).

On the other hand, a separation structure ISP located between another pair of the first emission area EA1 and the second emission area EA2, which extend in the fifth direction DR5 and are adjacent to each other in the fourth direction DR4, may extend in the fifth direction DR5 and may have a width smaller than a width of the non-emission area NEA in the fourth direction DR4 (e.g., a width corresponding to a distance between the another pair of the first emission area EA1 and the second emission area EA2).

In addition, in an area where two spacers SPC are located relatively close to each other, a separation structure ISP located between the two spacers SPC may have a relatively small size and may have a planar shape (e.g., a planar shape such as a trapezoid or a triangle) corresponding to the shape of a space between the two spacers SPC.

The shape and size of each of the spacers SPC and the separation structures ISP are not limited to those illustrated in FIG. 3 and can be variously changed according to embodiments. The structure and shape of the separation structures ISP according to embodiments will be described in detail later.

FIG. 4 is a cross-sectional view of a portion of the display panel 100 according to the embodiment. For example, FIG. 4 shows an embodiment of a cross-section of a portion of the display area DA corresponding to line X1-X1′ of FIG. 3. FIG. 4 shows a light emitting display panel including light emitting elements ED (e.g., organic light emitting diodes) as an example of the display panel 100 to which embodiments can be applied.

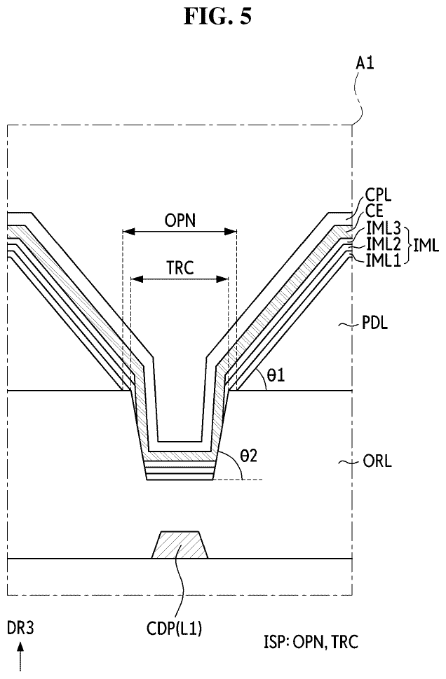

FIG. 5 is a detailed cross-sectional view of area A1 of FIG. 4. For example, FIG. 5 shows a separation structure ISP according to an embodiment in detail.

Referring to FIGS. 1 through 5, the display panel 100 according to the embodiment may include a substrate SUB, a circuit layer PCL, a light emitting element layer LEL, and an encapsulation member ENC. The substrate SUB, the circuit layer PCL, and the light emitting element layer LEL may form a display substrate (e.g., a TFT-OLED substrate) of the display panel 100. In an embodiment, the encapsulation member ENC may be an encapsulation substrate which is manufactured separately from the display substrate and then bonded onto the display substrate, and the display panel 100 may further include a filler FIL filling a space between the light emitting element layer LEL and the encapsulation member ENC. In an embodiment, the display panel 100 may further include another element, for example, an optical layer including a polarizing layer or a color filter layer, in addition to the elements illustrated in FIG. 4.

An encapsulation structure of the display panel 100 can be variously changed according to embodiments. For example, the encapsulation member ENC may be replaced with a thin-film encapsulation layer formed on the light emitting element layer LEL (e.g., a multilayer thin-film encapsulation layer formed directly on the light emitting element layer LEL and including inorganic layers and an organic layer between the inorganic layers), and the filler FIL may be omitted. Alternatively, the display panel 100 may include both the thin-film encapsulation layer and the encapsulation member ENC.

FIG. 4 shows an embodiment in which the display panel 100 includes the substrate SUB and the circuit layer PCL, the light emitting element layer LEL, the filler FIL and the encapsulation member ENC sequentially located on the substrate SUB. The circuit layer PCL, the light emitting element layer LEL, the filler FIL, and the encapsulation member ENC may overlap each other at least in the display area DA.

The substrate SUB is a base member for forming the display substrate and may include glass, polyimide, or other materials. The substrate SUB may have rigid or flexible properties and may be composed of a single layer or multiple layers.

The substrate SUB may include a display area DA and a non-display area NDA around the display area DA. Pixels PX may be located on the substrate SUB in the display area DA. The display area DA may include emission areas EA, from which light generated by the pixels PX is emitted, and a non-emission area NEA around the emission areas EA.

Each pixel PX may include a plurality of subpixels. For example, each pixel PX may include a first subpixel SP1, a second subpixel SP2, and a third subpixel SP3.

Each subpixel may include a light emitting element ED and a circuit element connected to the light emitting element ED. For example, the first subpixel SP1 may include a first light emitting element ED1 located in a first emission area EA1 and a transistor TFT1 electrically connected to the first light emitting element ED1. The first light emitting element ED1 refers to a light emitting element ED of the first subpixel SP1. The second subpixel SP2 may include a second light emitting element ED2 located in a second emission area EA2 and a transistor TFT1 electrically connected to the second light emitting element ED2. The second light emitting element ED2 refers to a light emitting element ED of the second subpixel SP2. The third subpixel SP3 may include a third light emitting element ED3 located in a third emission area EA3 and a transistor TFT1 electrically connected to the third light emitting element ED3. The third light emitting element ED3 refers to a light emitting element ED of the third subpixel SP3. The circuit elements of the subpixels, including the transistors TFT1, may be located in the circuit layer PCL of the display panel 100, and the light emitting elements ED of the subpixels may be located in the light emitting element layer LEL of the display panel 100.

Specifically, the circuit layer PCL may be located on the substrate SUB. The circuit layer PCL may include circuit elements included in each subpixel. For example, the circuit layer PCL may be a thin-film transistor layer which includes the transistors TFT1 included in each subpixel.

FIG. 4 shows, as an example of the circuit elements that may be included in the circuit layer PCL, one transistor TFT1, which is electrically connected to the light emitting element ED of a corresponding subpixel, among the circuit elements included in each subpixel. In an embodiment, the transistors TFT1 located in the circuit layer PCL may be thin-film transistors formed by a thin-film deposition process or the like.

The circuit layer PCL may further include wirings electrically connected to the subpixels. For example, the circuit layer PCL may further include signal lines and power lines electrically connected to the subpixels. The signal lines of the circuit layer PCL may include scan lines and data lines which respectively transmit scan signals and data signals to the subpixels. The power lines of the circuit layer PCL may include a first power line and a second power line which respectively transmit a high-potential first driving voltage and a low-potential second driving voltage to the subpixels. The circuit layer PCL may further include pads electrically connected to the wirings. The pads may be located in the non-display area NDA. In an embodiment, the circuit layer PCL may include a barrier layer BR, and the circuit elements, the wirings and the pads may be located on the barrier layer BR.

Specifically, the barrier layer BR may be located on the substrate SUB. The barrier layer BR may include a material suitable for protecting the transistors TFT1 and the light emitting elements ED from moisture introduced through the substrate SUB, for example, may include an inorganic insulating material. In an embodiment, the barrier layer BR may be composed of a plurality of inorganic insulating layers stacked alternately.

The transistors TFT1 may be located on the barrier layer BR. Each of the transistors TFT1 may include an active layer ACT1 and a gate electrode G1.

The active layer ACT1 may be located on the barrier layer BR. The active layer ACT1 may include a semiconductor material. For example, the active layer ACT1 may include polycrystalline silicon (e.g., low-temperature polycrystalline silicon), amorphous silicon, or an oxide semiconductor (e.g., indium gallium zinc oxide (IGZO), indium gallium zinc tin oxide (IGZTO) or indium gallium tin oxide (IGTO)).

The active layer ACT1 may include a channel region CHA1, a source region S1, and a drain region D1. The channel region CHA1 may be overlapped by the gate electrode G1 in the third direction DR3. The source region S1 may be located on a side of the channel region CHA1, and the drain region D1 may be located on the other side of the channel region CHA1. At least a portion of each of the source region S1 and the drain region D1 may not be overlapped by the gate electrode G1 in the third direction DR3. The conductivity (e.g., carrier concentration) of the source region S1 and the drain region D1 may be higher than the conductivity of the channel region CHA1.

A first insulating layer INS1 (e.g., a first gate insulating layer) may be located on the active layers ACT1.

A first conductive layer (e.g., a first gate metal layer) may be located on the first insulating layer INS1. The first conductive layer may include the gate electrode G1 of each transistor TFT1 and a first capacitor electrode CAE1 of each subpixel. The gate electrode G1 and the active layer ACT1 of each transistor TFT1 may overlap each other in the third direction DR3. For example, the gate electrode G1 of each transistor TFT1 may be located on the channel region CHA1 of the active layer ACT1. In an embodiment, when the gate electrode G1 of at least one transistor TFT1 is electrically connected to the first capacitor electrode CAE1 of a corresponding subpixel, the gate electrode G1 and the first capacitor electrode CAE1 may be integrally formed.

A second insulating layer INS2 (e.g., a second gate insulating layer) may be located on the first conductive layer.

A second conductive layer (e.g., a second gate metal layer) may be located on the second insulating layer INS2. The second conductive layer may include a second capacitor electrode CAE2 of each subpixel. The first capacitor electrode CAE1 and the second capacitor electrode CAE2 of each subpixel may overlap each other in the third direction DR3. A capacitor (e.g., a storage capacitor) of each subpixel may be formed by the first capacitor electrode CAE1, the second capacitor electrode CAE2, and the second insulating layer INS2.

A third insulating layer INS3 (e.g., an interlayer insulating layer) may be located on the second conductive layer.

A third conductive layer (e.g., a first source-drain metal layer) may be located on the third insulating layer INS3. The third conductive layer may include a first connection electrode PCE1 of each subpixel. The first connection electrode PCE1 may be electrically connected to a portion (e.g., the drain region D1) of each active layer ACT1 through a first contact hole PCT1 penetrating the first insulating layer INS1, the second insulating layer INS2, and the third insulating layer INS3.

A fourth insulating layer INS4 (e.g., a first planarization layer) may be located on the first connection electrodes PCE1 to planarize a step caused by the transistors TFT1.

A fourth conductive layer (e.g., a second source-drain metal layer) may be located on the fourth insulating layer INS4. The fourth conductive layer may include a second connection electrode PCE2 of each subpixel. The second connection electrode PCE2 may be electrically connected to the first connection electrode PCE1 through a second contact hole PCT2 penetrating the fourth insulating layer INS4.

In an embodiment, the fourth conductive layer may further include conductive patterns CDP in addition to the second connection electrodes PCE2 of the subpixels. Each of the conductive patterns CDP may be any one wiring L1 (or a portion of the wiring) or may be a connection electrode other than the second connection electrodes PCE2. For example, each of the conductive patterns CDP may be a signal line, such as a data line, or may be a power line such as the first power line.

An organic layer ORL (e.g., a second planarization layer) may be located on the second connection electrodes PCE2. The organic layer ORL may at least partially cover the circuit elements (e.g., the transistors TFT1) and the conductive patterns CDP (e.g., the wirings L1) included in the circuit layer PCL. The organic layer ORL may planarize a step caused by the circuit elements and the conductive patterns CDP of the circuit layer PCL.

Each of the barrier layer BR, the first insulating layer INS1, the second insulating layer INS2, and the third insulating layer INS3 may include at least one inorganic insulating layer including an inorganic insulating material (e.g., silicon nitride (SiNₓ), silicon oxynitride (SiON), silicon oxide (SiOₓ), titanium oxide (TiOₓ), or aluminum oxide (AlOₓ)). Each of the barrier layer BR, the first insulating layer INS1, the second insulating layer INS2, and the third insulating layer INS3 may be formed in a single-layer or multilayer structure.

Each of the first conductive layer, the second conductive layer, the third conductive layer, and the fourth conductive layer may include a conductive material (e.g., any one of molybdenum (Mo), aluminum (Al), chromium (Cr), gold (Au), titanium (Ti), nickel (Ni), neodymium (Nd) and copper (Cu), or an alloy thereof). Each of the first conductive layer, the second conductive layer, the third conductive layer, and the fourth conductive layer may be formed in a single-layer or multilayer structure.

Each of the fourth insulating layer INS4 and the organic layer ORL may include at least one organic insulating layer including an organic insulating material (e.g., acryl resin, epoxy resin, phenolic resin, polyamide resin, or polyimide resin). Each of the fourth insulating layer INS4 and the organic layer ORL may be formed in a single-layer or multilayer structure.

The light emitting element layer LEL may be located on the organic layer ORL. The light emitting element layer LEL may include the light emitting elements ED (e.g., the first light emitting element ED1, the second light emitting element ED2, and the third light emitting element ED3) of each pixel PX, a pixel defining layer PDL, and a spacer SPC. In an embodiment, the light emitting element layer LEL may further include a capping layer CPL which covers the light emitting elements ED.

The pixel defining layer PDL may be located on the organic layer ORL to define or separate the emission areas EA. For example, the pixel defining layer PDL may include openings corresponding to the emission areas EA and may be located in the non-emission area NEA to surround the emission areas EA. In an embodiment, the pixel defining layer PDL may cover edge portions of first electrodes AE of the light emitting elements ED and may be opened to expose other portions including central portions of the first electrodes AE. An area where the first electrode AE of each of the light emitting elements ED is exposed may correspond to the emission area EA of each pixel PX, and a light emitting layer EML, etc. may be located on a portion of the first electrode AE which is not covered with the pixel defining layer PDL. The pixel defining layer PDL may also be referred to as a “bank”.

In an embodiment, the pixel defining layer PDL may include an organic insulating material. For example, the pixel defining layer PDL may include at least one organic insulating layer including acryl resin, epoxy resin, phenolic resin, polyamide resin, or polyimide resin.

The pixel defining layer PDL and the organic layer ORL under the pixel defining layer PDL may include the same material or different materials.

The spacer SPC may be located on a portion of the pixel defining layer PDL. The spacer SPC may include an organic insulating material. The pixel defining layer PDL and the spacer SPC may include the same material or different materials. The pixel defining layer PDL and the spacer SPC may be formed sequentially through respective mask processes or may be formed simultaneously or integrally using a halftone mask.

Each light emitting element ED may include the first electrode AE located in each emission area EA and at least one light emitting layer EML and a second electrode CE sequentially located on the first electrode AE. In an embodiment, each light emitting element ED may have a tandem structure which includes a plurality of light emitting layers EML located on the first electrode AE and at least one intermediate layer IML located between the light emitting layers EML.

For example, the first light emitting element ED1 may include a first electrode AE located in the first emission area EA1, a first intermediate layer IML1 located on the first electrode AE, a first light emitting layer EML1 located on the first intermediate layer IML1, a second intermediate layer IML2 located on the first light emitting layer EML1, another first light emitting layer EML1 located on the second intermediate layer IML2, a third intermediate layer IML3 located on the another first light emitting layer EML1, and the second electrode CE located on the third intermediate layer IML3. The second light emitting element ED2 may include a first electrode AE located in the second emission area EA2, a first intermediate layer IML1 located on the first electrode AE, a second light emitting layer EML2 located on the first intermediate layer IML1, a second intermediate layer IML2 located on the second light emitting layer EML2, another second light emitting layer EML2 located on the second intermediate layer IML2, a third intermediate layer IML3 located on the another second light emitting layer EML2, and the second electrode CE located on the third intermediate layer IML3. The third light emitting element ED3 may include a first electrode AE located in the third emission area EA3, a first intermediate layer IML1 located on the first electrode AE, a third light emitting layer EML3 located on the first intermediate layer IML1, a second intermediate layer IML2 located on the third light emitting layer EML3, another third light emitting layer EML3 located on the second intermediate layer IML2, a third intermediate layer IML3 located on the another third light emitting layer EML3, and the second electrode CE located on the third intermediate layer IML3. However, embodiments are not limited to this example. For example, at least one light emitting element ED may include a single light emitting layer EML.

The first electrode AE of each light emitting element ED may be located on the organic layer ORL. The first electrode AE of each light emitting element ED may be electrically connected to the transistor TFT1 included in a corresponding subpixel. For example, the first electrode AE of the first light emitting element ED1 may be electrically connected to the transistor TFT1 included in the first subpixel SP1, the first electrode AE of the second light emitting element ED2 may be electrically connected to the transistor TFT1 included in the second subpixel SP2, and the first electrode AE of the third light emitting element ED3 may be electrically connected to the transistor TFT1 included in the third subpixel SP3.

The first electrode AE of each light emitting element ED may have a size and shape corresponding to those of an emission area EA, and most of the first electrode AE may be located in the emission area EA. An edge portion of the first electrode AE of each light emitting element ED may be located in the non-emission area NEA around the emission area EA and may be covered with the pixel defining layer PDL.

The first electrode AE of each light emitting element ED may be a single-layer or multilayer electrode including at least one conductive material. In an embodiment, the display panel 100 may be a top emission display panel, and the first electrode AE may include a reflective electrode layer including a material having high reflectivity (e.g., a metal).

The light emitting layers EML of each light emitting element ED may include a high-molecular or low-molecular material. For example, each light emitting layer EML may include a high-molecular or low-molecular organic material which emits light of a specific color (e.g., a first color, a second color, or a third color). Light emitted from the light emitting layers EML may contribute to image display.

In an embodiment, at least one light emitting layer EML (e.g., two first light emitting layers EML1) included in the first light emitting element ED1, at least one light emitting layer EML (e.g., two second light emitting layers EML2) included in the second light emitting element ED2, and at least one light emitting layer EML (e.g., two third light emitting layers EML3) included in the third light emitting element ED3 may be individually located in their respective emission areas EA and may emit light of different colors. For example, the first light emitting layers EML1 of the first light emitting element ED1 may be organic light emitting layers which emit light of the first color (e.g., light in a red wavelength band) and may include the same material or different materials. Peak wavelengths of the light emitted from the first light emitting layers EML1 may be the same or different. The second light emitting layers EML2 of the second light emitting element ED2 may be organic light emitting layers which emit light of the second color (e.g., light in a green wavelength band) and may include the same material or different materials. Peak wavelengths of the light emitted from the second light emitting layers EML2 may be the same or different. The third light emitting layers EML3 of the third light emitting element ED3 may be organic light emitting layers which emit light of the third color (e.g., light in a blue wavelength band) and may include the same material or different materials. Peak wavelengths of the light emitted from the third light emitting layers EML may be the same or different.

However, embodiments are not limited to this case. For example, in an embodiment, the light emitting layers EML included in the first light emitting element ED1, the second light emitting element ED2 and the third light emitting element ED3 may be placed as common layers in the entire display area DA, and the first light emitting element ED1, the second light emitting element ED2 and the third light emitting element ED3 may emit light of the same color. In this case, a light conversion layer or a color filter layer may be placed on at least one of the first light emitting element ED1, the second light emitting element ED2, and the third light emitting element ED3 to convert the color or wavelength of light emitted from each emission area EA.

Each intermediate layer IML may be located between the first electrode AE and the second electrode CE of each of the light emitting elements ED and may overlap the light emitting layers EML of each of the light emitting elements ED. Each intermediate layer IML may include at least one of a hole injection layer, a hole transport layer, a charge generation layer, an electron transport layer, and an electron injection layer. In addition, each intermediate layer IML may be composed of a single layer or multiple layers.

For example, the first intermediate layer IML1 may include a hole injection layer and a hole transport layer sequentially stacked on the first electrode AE of each of the light emitting elements ED. The second intermediate layer IML2 may include an electron transport layer, an n-type charge generation layer, a p-type charge generation layer, and a hole transport layer sequentially stacked on a first light emitting layer EML of each of the light emitting elements ED. The third intermediate layer IML3 may include an electron transport layer located between a second light emitting layer EML of each of the light emitting elements ED and the second electrode CE.

In an embodiment, the intermediate layers IML may be formed as common layers located over the entire display area DA. In each emission area EA, the intermediate layers IML may be located between the first electrode AE and the second electrode CE of each of the light emitting elements ED, and the light emitting layers EML of each of the light emitting elements ED may be located between the intermediate layers IML. In the non-emission area NEA, the intermediate layers IML may be sequentially stacked on the pixel defining layer PDL and the spacer SPC and may be covered with the second electrode CE of the light emitting elements ED and the capping layer CPL.

When the intermediate layers IML are formed as common layers, there may be an increased risk of generation of lateral leakage current between adjacent light emitting elements ED through the intermediate layers IML. When the lateral leakage current is generated, color mixing may occur between subpixels, which may deteriorate image quality. However, the display panel 100 according to embodiments may include separation structures ISP distributed in the non-emission area NEA, and the intermediate layers IML may be partially broken or separated by each separation structure ISP. Accordingly, the lateral leakage current of the display panel 100 can be effectively reduced or blocked.

The second electrode CE of each light emitting element ED may include a conductive material. In an embodiment, the second electrode CE may be formed as a common layer located over the entire display area DA. For example, the second electrode CE may be located over the entire display area DA including the emission areas EA and the non-emission area NEA. In an embodiment, the display panel 100 may be a top emission display panel, and the second electrode CE may include a transparent or translucent electrode layer.

The capping layer CPL may be located on the light emitting elements ED. The capping layer CPL may be located over the entire display area DA to entirely cover the light emitting elements ED. The capping layer CPL may include a material suitable for protecting the light emitting elements ED, for example, an inorganic insulating material and may be optically transparent so as to transmit light generated by the light emitting elements ED. In an embodiment, the capping layer CPL may be composed of a plurality of inorganic insulating layers stacked alternately. In an embodiment, refractive indices of the inorganic insulating layers included in the capping layer CPL may be adjusted so that light generated by the light emitting elements ED can be more effectively emitted.

The filler FIL may be located between the light emitting element layer LEL and the encapsulation member ENC. The filler FIL may include a material, such as resin, and may be optically transparent. The filler FIL may absorb impact, which may be applied to the display panel 100, and may maintain a uniform distance between the light emitting element layer LEL and the encapsulation member ENC.

The encapsulation member ENC may be located on a surface of the substrate SUB on which the circuit layer PCL, the light emitting element layer LEL, etc. are formed. For example, the encapsulation member ENC may be located on the light emitting element layer LEL and the filler FIL. In an embodiment, the substrate SUB and the encapsulation member ENC may be bonded to each other with the filler FIL. The filler FIL may be located between the substrate SUB and the encapsulation member ENC. In an embodiment, the encapsulation member ENC may include glass, polyimide, or other materials. The substrate SUB and the encapsulation member ENC may include the same material or different materials.

The display panel 100 according to embodiments may include separation structures ISP located in the non-emission area NEA. The separation structures ISP according to the embodiments may be formed in the organic layer ORL and the pixel defining layer PDL. For example, each separation structure ISP may include an opening OPN penetrating one of the organic layer ORL and the pixel defining layer PDL and a groove TRC recessed into a surface of the other one of the organic layer ORL and the pixel defining layer PDL. In addition, the opening OPN and the groove TRC may spatially overlap each other. For example, the opening OPN and the groove TRC may be placed continuously or in close proximity to each other at a position corresponding to each separation structure ISP and may overlap each other in the third direction DR3. The opening OPN of each separation structure ISP may be in the form of a through-hole formed in at least one organic insulating layer such as the pixel defining layer PDL or the organic layer ORL. The opening OPN of each separation structure ISP may also be referred to as a “fractured part” or a “through-hole.”

In an embodiment, as illustrated in FIG. 5, each separation structure ISP may include an opening OPN penetrating the pixel defining layer PDL and a groove TRC recessed into a surface of the organic layer ORL under the opening OPN.

In FIG. 5, an area where the pixel defining layer PDL is completely perforated is indicated as the opening OPN. However, the opening OPN may not be formed perfectly vertically, but rather at an inclined angle. In this case, the opening OPN may be defined by a sidewall portion of a boundary between the pixel defining layer PDL and the opening OPN and may have a width that gradually changes in the third direction DR3.

In an embodiment, a width or area of the groove TRC may be smaller than a width or area of the opening OPN. In addition, the groove TRC may completely overlap the opening OPN and may be located inside an area where the opening OPN is formed. For example, the groove TRC may have a smaller width than the opening OPN, and both ends of the groove TRC in a width direction of each separation structure ISP may be located at positions spaced apart from both ends of the opening OPN. For example, in the width direction of each separation structure ISP, sidewalls of the groove TRC and sidewalls of the opening OPN may be located at positions spaced apart from each other. In addition, in the width direction of each separation structure ISP, the sidewalls of the groove TRC may be located inside the area where the opening OPN is formed. For example, in the width direction of each separation structure ISP, the groove TRC may be located in a center of the opening OPN.

In an embodiment, the groove TRC may have a shape or size that may cause partial breaking or separation of at least one common layer (e.g., the intermediate layers IML shared by the light emitting elements ED) formed over the entire display area DA. For example, the sidewalls of the groove TRC may include an inclined surface which slopes at a greater angle θ2 than the sidewalls of the opening OPN and may have a shape closer to the vertical than the sidewalls of the opening OPN. For example, the groove TRC may be formed to have sidewalls which slope at an angle θ2 that may cause partial breaking or separation of the intermediate layers IML. In an embodiment, the sidewalls of the groove TRC may have a slope of 70 degrees or more, for example, a slope corresponding to an angle θ2 of 70 to 90 degrees. Alternatively, the groove TRC may be formed to include sidewalls having a reverse-tapered shape. When the sidewalls of the groove TRC include an inclined surface with a slope of 70 degrees or more, the intermediate layers IML can be appropriately broken or separated in an area where the groove TRC is formed. For example, at least one of the intermediate layers IML may be broken or separated in the area where the groove TRC is located. Alternatively, even when the intermediate layers IML are not completely broken in the area where the groove TRC is formed, a thickness of the intermediate layers IML may be significantly reduced in a sidewall portion of the groove TRC, thereby obtaining the effect of reducing or blocking lateral leakage current between the light emitting elements ED. In an embodiment, when the sidewalls of the groove TRC have a taper angle θ2 of 70 to 90 degrees, the groove TRC can be easily formed by a dry process. For example, the groove TRC having a slope corresponding to the angle θ2 of 70 to 90 degrees can be easily formed by a dry ashing or dry etching process.

The groove TRC may serve as a separator that reduces or blocks lateral leakage current between the light emitting elements ED. The groove TRC may reduce or prevent optical or electrical interference between the subpixels or the pixels PX and may improve the image quality and reliability of the display panel 100, and the display device 10 and the electronic device 1 including the display panel 10. Unlike in the embodiments, when the sidewalls of the groove TRC have a gentle slope of less than 70 degrees, the intermediate layers IML are highly likely to be formed continuously without being broken in the groove TRC. Therefore, the lateral leakage current between the light emitting elements ED may not be properly blocked. The lateral leakage current may cause color mixing between adjacent subpixels.

Although FIGS. 4 and 5 disclose an embodiment in which the sidewalls of the groove TRC are formed as inclined surfaces having a constant slope, embodiments are not limited to this case. For example, the sidewalls of the groove TRC may also be formed as curved surfaces having a gradually changing slope. In this case, when the slope of the sidewalls of the groove TRC is 70 degrees or more, it may be based on a maximum slope among the slopes of the sidewalls of the groove TRC.

In an embodiment, the openings OPN of the separation structures ISP may be formed in a process of patterning the pixel defining layer PDL to open the pixel defining layer PDL at positions corresponding to the emission areas EA. For example, after an organic insulating layer is formed on the organic layer ORL and the first electrodes AE of the light emitting elements ED, a photolithography process and an etching process may be performed to form the pixel defining layer PDL from the organic insulating layer. In this process, the openings OPN of the separation structures ISP may be formed in the non-emission area NEA. Accordingly, the openings OPN of the separation structures ISP may be formed without adding an additional process, thereby increasing the manufacturing efficiency of the display panel 100. In this case, the sidewalls of the openings OPN may have a slope within a range that can be formed by the process of patterning the organic insulating layer using the photolithography process. For example, the sidewalls of the openings OPN may have a slope corresponding to an angle θ1 of less than 70 degrees, for example, a slope corresponding to an angle θ1 of about 40 to 50 degrees or about 40 to 60 degrees.

Since the pixel defining layer PDL is opened at a position where each separation structure ISP is located, gas or moisture released from the pixel defining layer PDL may be reduced. For example, the amount of gas or moisture released from the pixel defining layer PDL by external light such as sunlight may be reduced. Accordingly, deterioration of the display panel 100, and the display device 10 and the electronic device 1 including the display panel 100 can be improved.

In addition, since the groove TRC is formed in the organic layer ORL at the position where each separation structure ISP is located, the intermediate layers IML of the light emitting elements ED, which are formed as common layers in the display area DA, may be partially broken or separated by the groove TRC. Accordingly, leakage current (e.g., lateral leakage current) between the light emitting elements ED can be reduced or blocked.

Additionally, in embodiments, the opening OPN and the groove TRC of each separation structure ISP spatially overlap each other. Therefore, the openings OPN and the grooves TRC of the separation structures ISP can be placed more efficiently in the limited non-emission area NEA. For example, it is possible to improve the deterioration of the display panel 100 by forming the openings OPN in the pixel defining layer PDL in the non-emission area NEA and possible to increase the number or size of the grooves TRC that can be placed in the non-emission area NEA by placing the groove TRC inside each of the openings OPN. Accordingly, the leakage current between the light emitting elements ED can be reduced or blocked more effectively, and the image quality and reliability of the display panel 100, and the display device 10 and the electronic device 1 including the display panel 100 can be effectively improved.

In embodiments, one of the pixel defining layer PDL and the organic layer ORL may remain to a certain thickness under each separation structure ISP. For example, the groove TRC of each separation structure ISP may be formed by removing the organic layer ORL only to a certain thickness, and the organic layer ORL may remain under the groove TRC. Accordingly, even if there is a conductive pattern CDP under a separation structure ISP, the conductive pattern CDP may be stably covered with the organic layer ORL. Therefore, according to the embodiments, the separation structures ISP can be placed in the non-emission area NEA regardless of patterns included in a conductive layer (e.g., the fourth conductive layer including the conductive patterns CDP and the second connection electrodes PCE2) under the organic layer ORL. For example, the separation structures ISP may be placed on the conductive patterns CDP even at positions where the conductive patterns CDP are located under the organic layer ORL. Accordingly, the separation structures ISP can be more freely placed or formed, and a more continuous and larger separation structure ISP can be formed in a space secured between the spacers SPC within the non-emission area NEA. Accordingly, the deterioration improvement effect and the leakage current reduction effect of the separation structures ISP can be maximized.

FIG. 6 is a cross-sectional view of a portion of a display panel 100 according to an embodiment. For example, FIG. 6 shows an embodiment of a cross-section of a portion of a display area DA corresponding to line X1-X1′ of FIG. 3.

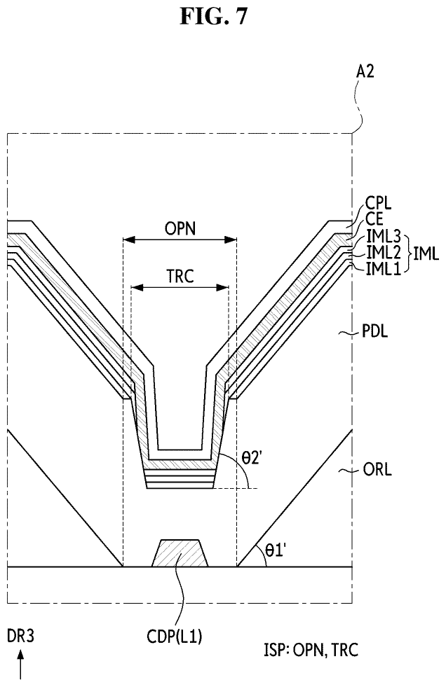

FIG. 7 is a detailed cross-sectional view of area A2 of FIG. 6. For example, FIG. 7 shows a separation structure ISP according to an embodiment in detail.

FIGS. 6 and 7 show a different embodiment from FIGS. 4 and 5 in relation to separation structures ISP. In the description of the embodiment of FIGS. 6 and 7, a detailed description of elements substantially identical or similar to those of the embodiment of FIGS. 4 and 5 will be omitted.

Referring to FIGS. 6 and 7, each separation structure ISP according to an embodiment may include an opening OPN penetrating an organic layer ORL and a groove TRC recessed into a surface of a pixel defining layer PDL in a portion covering the opening OPN. In an embodiment, a width or area of the groove TRC may be smaller than a width or area of the opening OPN. In addition, the groove TRC may completely overlap the opening OPN and may be located inside an area where the opening OPN is formed. For example, the groove TRC may have a smaller width than the opening OPN, and both ends of the groove TRC in a width direction of each separation structure ISP may be located at positions spaced apart from both ends of the opening OPN. In addition, in the width direction of each separation structure ISP, both ends of the groove TRC may be located inside the area where the opening OPN is formed. However, embodiments are not limited to this case. For example, the groove TRC may also have a greater width than the opening OPN, and sidewalls of the groove may partially overlap sidewalls of the opening OPN.

In an embodiment, the opening OPN of each separation structure ISP may be formed together with a via hole in a process of forming the via hole which penetrates the organic layer ORL to connect a light emitting element ED of each subpixel to a second connection electrode PCE2. Accordingly, the opening OPN of each separation structure ISP may be formed without adding an additional process, thereby increasing the manufacturing efficiency of the display panel 100. In an embodiment, the opening OPN of each separation structure ISP may be formed at a gentle angle θ1′, compared with the groove TRC. The inclination angle θ1′ of the sidewalls of the opening OPN may vary depending on the size of the opening OPN, the shape of the opening OPN, or a process method or process conditions applied to the formation of the opening OPN.

Since the organic layer ORL is opened at a position where each separation structure ISP is located, gas or moisture released from the organic layer ORL may be reduced. For example, the amount of gas or moisture released from the organic layer ORL by external light such as sunlight may be reduced. Accordingly, deterioration of the display panel 100, and the display device 10 and the electronic device 1 including the display panel 100 can be improved.

In an embodiment, the groove TRC of each separation structure ISP may have sidewalls with a slope suitable for causing substantial breaking of intermediate layers IML. For example, the sidewalls of the groove TRC may have a slope corresponding to an angle θ2′ of 70 degrees or more, for example, a slope corresponding to an angle θ2′ of 70 to 90 degrees.

Since the groove TRC is formed in the pixel defining layer PDL at the position where each separation structure ISP is located, the intermediate layers IML of light emitting elements ED, which are formed as common layers in the display area DA, may be partially broken or separated by the groove TRC. Accordingly, leakage current between the light emitting elements ED can be reduced or blocked.

Additionally, in the embodiment of FIGS. 6 and 7, the opening OPN and the groove TRC of each separation structure ISP spatially overlap each other. Therefore, the openings OPN and the grooves TRC of the separation structures ISP can be placed more efficiently in a non-emission area NEA. Accordingly, the image quality and reliability of the display panel 100, and the display device 10 and the electronic device 1 including the display panel 100 can be effectively improved.

In addition, in the embodiment of FIGS. 6 and 7, one of the pixel defining layer PDL and the organic layer ORL may remain to a certain thickness under each separation structure ISP. For example, the groove TRC of each separation structure ISP may be formed by removing the pixel defining layer PDL only to a certain thickness, and the pixel defining layer PDL may remain under the groove TRC. Accordingly, even if there is a conductive pattern CDP under a separation structure ISP, the conductive pattern CDP may be stably covered with the pixel defining layer PDL. Therefore, according to embodiments, the separation structures ISP can be placed in the non-emission area NEA regardless of patterns included in a conductive layer (e.g., a fourth conductive layer including conductive patterns CDP and second connection electrodes PCE2) under the pixel defining layer PDL and the organic layer ORL. Accordingly, the separation structures ISP can be more freely placed or formed, and a more continuous and larger separation structure ISP can be formed in a space secured between spacers SPC within the non-emission area NEA. Accordingly, the deterioration improvement effect and the leakage current reduction effect of the separation structures ISP can be maximized.

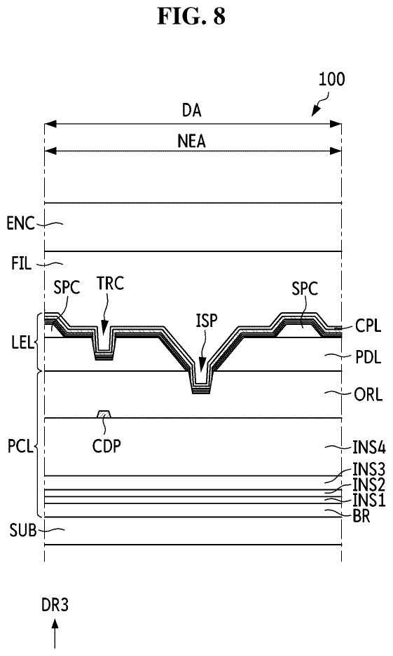

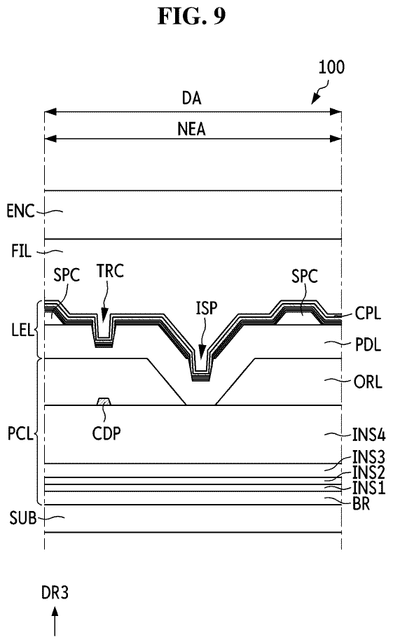

FIG. 8 is a cross-sectional view of a portion of a display panel 100 according to an embodiment. FIG. 9 is a cross-sectional view of a portion of a display panel 100 according to an embodiment. For example, FIGS. 8 and 9 each show a portion of a non-emission area NEA included in a display area DA of the display panel 100. FIG. 8 shows a portion of a non-emission area NEA including a separation structure ISP according to the embodiment of FIGS. 4 and 5, and FIG. 9 shows a portion of a non-emission area NEA including a separation structure ISP according to the embodiment of FIGS. 6 and 7.

Referring to FIGS. 8 and 9 in addition to FIGS. 3 through 7, a display panel 100 according to embodiments may include a separation structure ISP including an opening OPN and a groove TRC and may further include a groove TRC recessed into a surface of a pixel defining layer PDL at a position spaced apart from the separation structure ISP. For example, a small-sized groove TRC may be additionally formed in a portion of the non-emission area NEA of FIG. 3 where spacers SPC and separation structures ISP are not located. Alternatively, some of the separation structures ISP of FIG. 3 may be modified to include only a groove TRC of the pixel defining layer PDL without including an opening OPN penetrating the pixel defining layer PDL or an organic layer ORL.

In an embodiment, depending on the presence or absence of conductive patterns CDP located between a fourth insulating layer INS4 and the organic layer ORL, only a groove TRC of the pixel defining layer PDL may be formed in a portion of the non-emission area NEA, and a separation structure ISP may be formed in another portion of the non-emission area NEA. For example, only a groove TRC of the pixel defining layer PDL may be formed in a portion of the non-emission area NEA where each of the conductive patterns CDP is located, and a separation structure ISP including an opening OPN and a groove TRC may be formed in another portion of the non-emission area NEA where the conductive patterns CDP are not located. For example, the separation structures ISP may not overlap the conductive patterns CDP. Accordingly, the conductive patterns CDP can be more stably covered, thereby enhancing the electrical stability of the display panel 100.

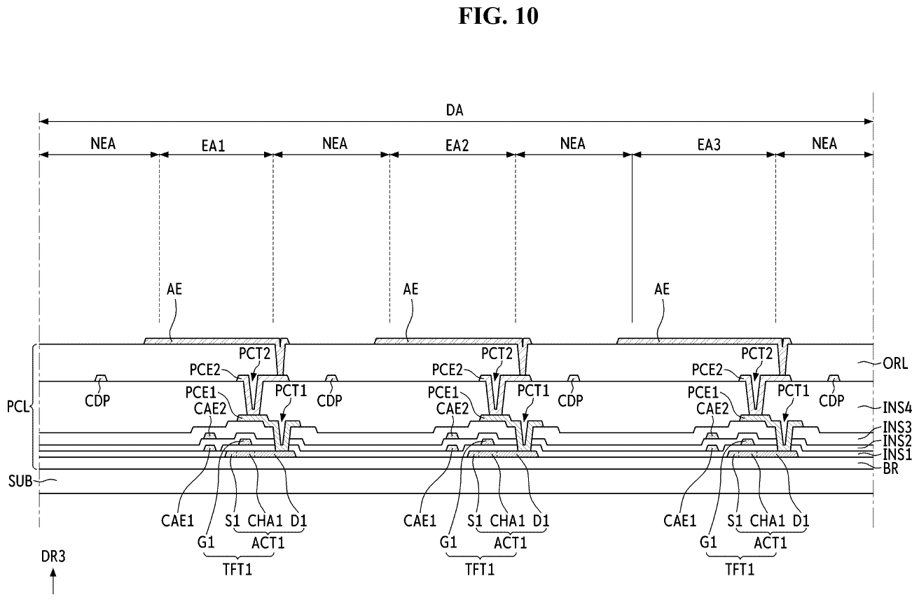

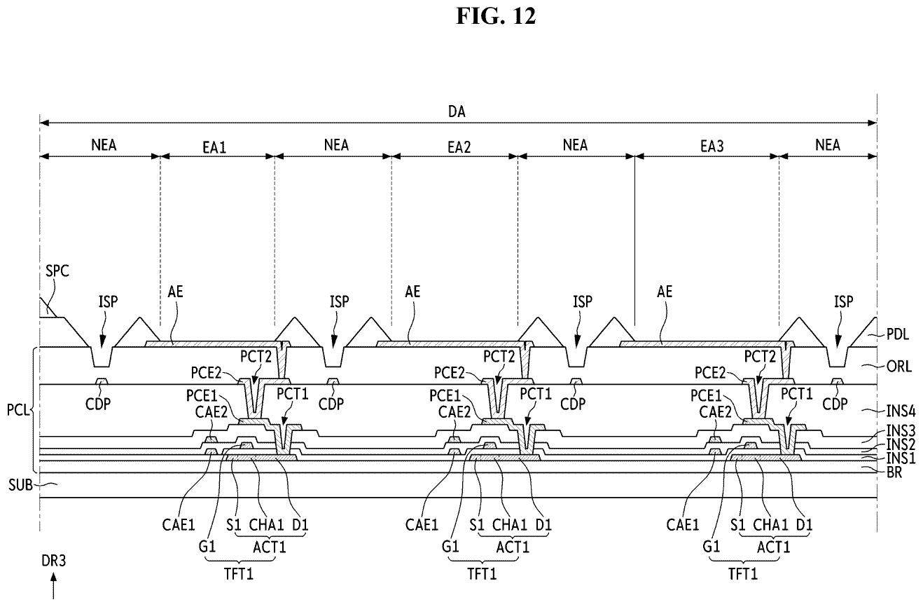

FIGS. 10 through 14 are cross-sectional views illustrating a method of manufacturing a display device according to an embodiment. For example, FIGS. 10 through 14 sequentially show manufacturing operations for forming separation structures ISP and a light emitting element layer LEL among manufacturing operations for manufacturing the display panel 100 according to the embodiment of FIGS. 4 and 5.

Referring to FIG. 10, a circuit layer PCL may be formed on a substrate SUB, and first electrodes AE of light emitting elements ED may be formed on the circuit layer PCL. The forming of the circuit layer PCL may include forming circuit elements of subpixels, which include transistors TFT1, and conductive patterns CDP on the substrate SUB and forming an organic layer ORL on the circuit elements and the conductive patterns CDP.

The forming of the first electrodes AE of the light emitting elements ED may include forming the first electrodes AE of the light emitting elements ED, which are to be included in the subpixels, in emission areas EA of a display area DA, respectively. For example, a conductive film may be formed on the organic layer ORL using at least one conductive material. Then, the conductive film may be etched and patterned into shapes corresponding to the first electrodes AE of the light emitting elements ED to form the first electrodes AE of the light emitting elements ED in the emission areas EA, respectively.

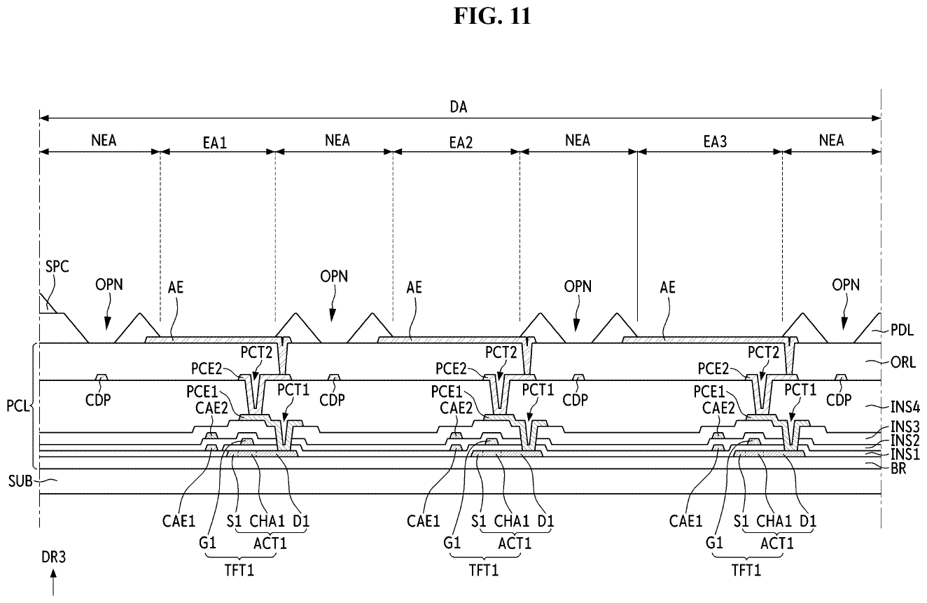

Referring to FIG. 11, a pixel defining layer PDL and a spacer SPC may be formed on the organic layer ORL and the first electrodes AE of the light emitting elements ED. For example, the pixel defining layer PDL may be formed in a non-emission area NEA by performing a process of forming an organic insulating layer using at least one organic insulating material exemplified above and a process of etching the organic insulating layer. In an embodiment, the organic insulating layer may be patterned into the pixel defining layer PDL by etching the organic insulating layer according to the intended shape of the pixel defining layer PDL by performing a photolithography process and an etching process. However, a method of patterning the organic insulating layer to form the pixel defining layer PDL is not limited to this example.

In an embodiment, the pixel defining layer PDL and the spacer SPC may be formed simultaneously by forming or etching the organic insulating layer to a different thickness in each part using a halftone mask. Alternatively, the pixel defining layer PDL and the spacer SPC may be formed sequentially using different masks.

The pixel defining layer PDL may define the emission areas EA in which the first electrodes AE of the light emitting elements ED are exposed and may be formed in the non-emission area NEA surrounding the emission areas EA. For example, the pixel defining layer PDL may be opened to cover edges of the first electrodes AE and expose the other regions of the first electrodes AE.

In an embodiment, the pixel defining layer PDL may also be opened to include a plurality of openings OPN in the non-emission area NEA. For example, a plurality of openings OPN may be formed in the pixel defining layer PDL by removing the organic insulating layer at positions where separation structures ISP are to be placed, respectively. Since the pixel defining layer PDL is opened in the non-emission area NEA, the organic layer ORL may be exposed in areas where the openings OPN are formed in the pixel defining layer PDL.

Referring to FIGS. 5, 11 and 12, a separation structure ISP may be formed in the non-emission area NEA by forming a groove TRC in the organic layer ORL under each of the openings OPN of the pixel defining layer PDL. For example, a groove TRC may be formed in the organic layer ORL by removing the organic layer ORL under each of the openings OPN of the pixel defining layer PDL by a certain thickness using a mask which selectively exposes only a portion of the organic layer ORL located under a central portion of each of the openings OPN of the pixel defining layer PDL. In an embodiment, the groove TRC may be formed in the organic layer ORL such that sidewalls of the groove TRC have an inclined surface with a slope within a selected range by controlling a process method or process conditions. For example, the organic layer ORL under each of the openings OPN of the pixel defining layer PDL may be removed by a certain thickness by performing a dry process (e.g., a dry ashing or dry etching process). As a result, the groove TRC may be formed in the organic layer ORL such that the sidewalls of the groove TRC have a slope of 70 to 90 degrees or have a reverse-tapered shape. In an embodiment, the groove TRC of the organic layer ORL may be formed to include sidewalls having a greater slope than sidewalls of each of the openings OPN of the pixel defining layer PDL. When a display panel 100, which includes an additional groove TRC in addition to the separation structure ISP as in the embodiment of FIG. 8, is manufactured, the groove TRC of the separation structure ISP may be formed in the organic layer ORL, and at the same time, an additional groove TRC may be further formed in the pixel defining layer PDL at a position spaced apart from the separation structure ISP.

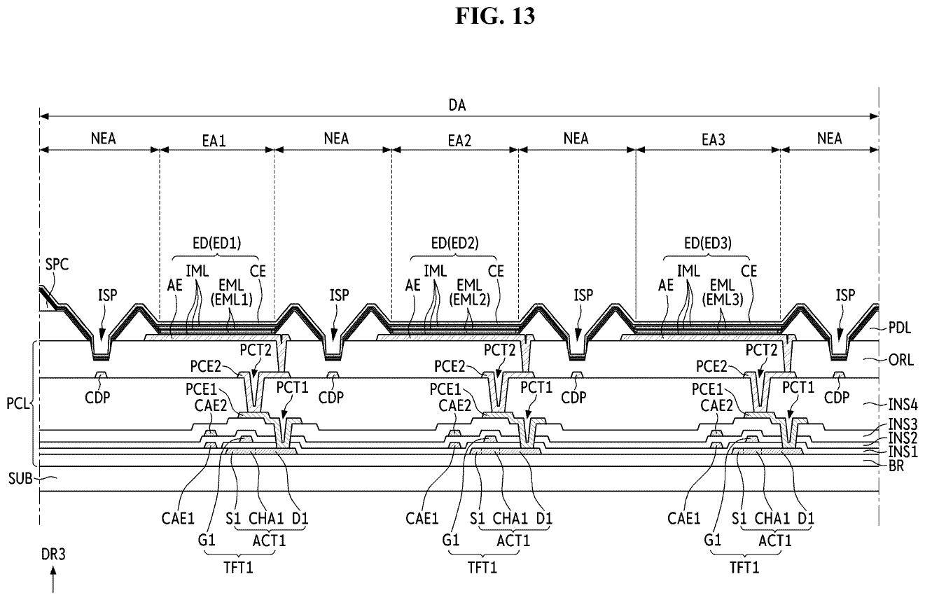

Referring to FIG. 13, at least one intermediate layer IML, at least one light emitting layer EML, and a second electrode CE may be formed in each of the emission areas EA to form each of the light emitting elements ED. For example, a first intermediate layer IML1 (see FIG. 5), one light emitting layer EML, a second intermediate layer IML2 (see FIG. 5), another light emitting layer EML, a third intermediate layer IML3 (see FIG. 5), and the second electrode CE may be sequentially formed on the first electrode AE of each of the light emitting elements ED.

In an embodiment, each light emitting layer EML may be individually formed in each emission area EA. For example, each light emitting layer EML may be formed in each emission area EA using a fine metal mask or the like.

In an embodiment, the intermediate layers IML and the second electrode CE may be formed as common layers over the entire display area DA. For example, each of the intermediate layers IML and the second electrode CE may be formed (e.g., fully deposited) over the entire display area DA including the emission areas EA and the non-emission area NEA.

When the separation structures ISP are formed in the non-emission area NEA, at least one of the intermediate layers IML may be partially broken or separated by the separation structures ISP. For example, the intermediate layers IML may be broken or may be formed to a significantly thin thickness in an area where the groove TRC of each of the separation structures ISP is located (e.g., at the sidewalls of the groove TRC). As a result, the intermediate layers IML may be substantially broken or separated.

In an embodiment, the second electrode CE may have a step corresponding to each of the separation structures ISP or may be partially broken by a groove TRC in at least one of the separation structures ISP.

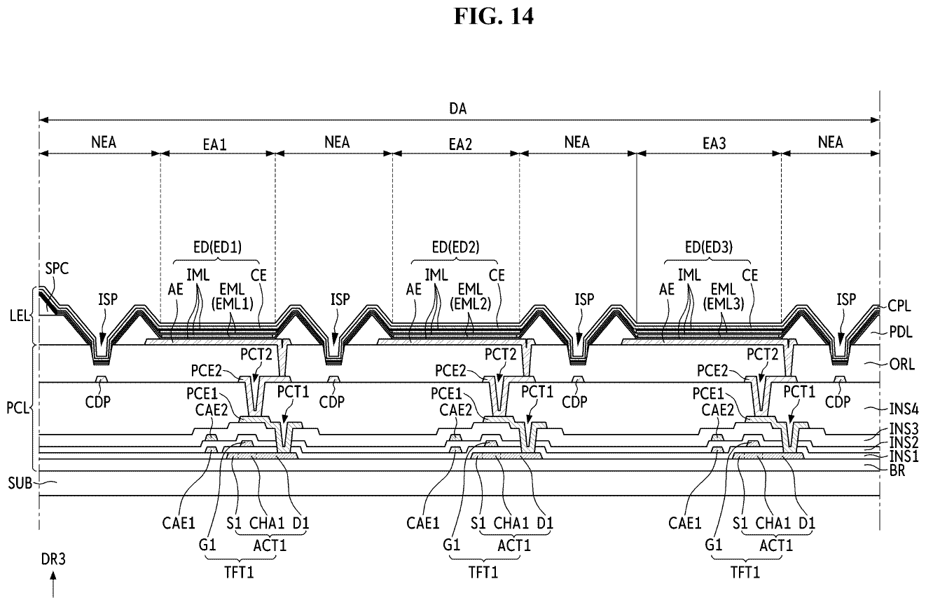

Referring to FIG. 14, a capping layer CPL may be formed on the light emitting elements ED. For example, the capping layer CPL may be formed over the entire display area DA to cover the light emitting elements ED. The capping layer CPL may be formed as a single-layer or multilayer inorganic layer including a material exemplified above, for example, at least one inorganic insulating material. Accordingly, a display substrate including the circuit layer PCL and the light emitting element layer LEL may be formed.

Next, the filler FIL and the encapsulation member ENC of FIG. 4 may be placed on the display substrate, and the encapsulation member ENC (e.g., an encapsulating substrate) may be bonded onto the display substrate to encapsulate the light emitting element layer LEL. Alternatively, a thin-film encapsulation layer, instead of the encapsulation member ENC, may be formed on the light emitting element layer LEL to encapsulate the light emitting element layer LEL. Accordingly, the display panel 100 including the separation structures ISP according to the embodiment of FIGS. 4 and 5 may be manufactured.

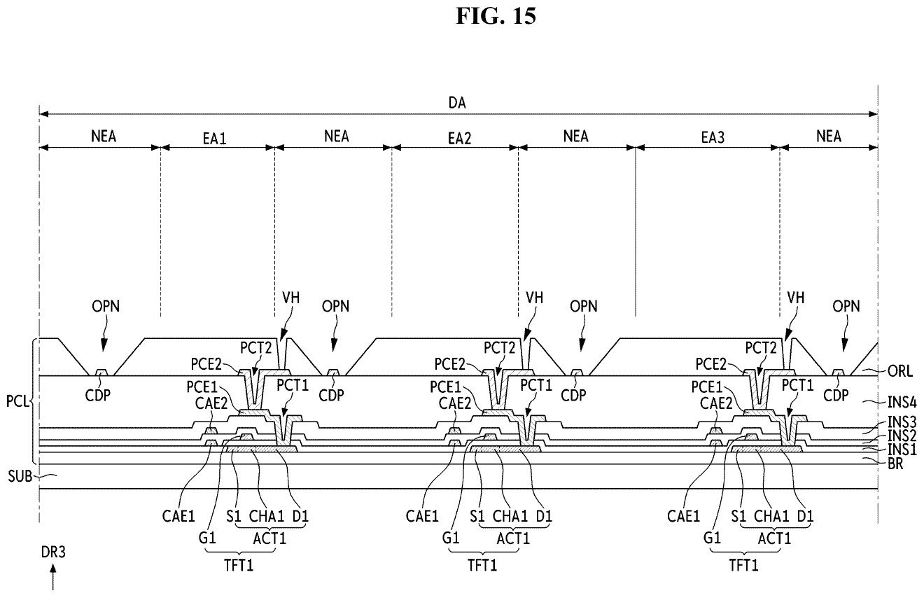

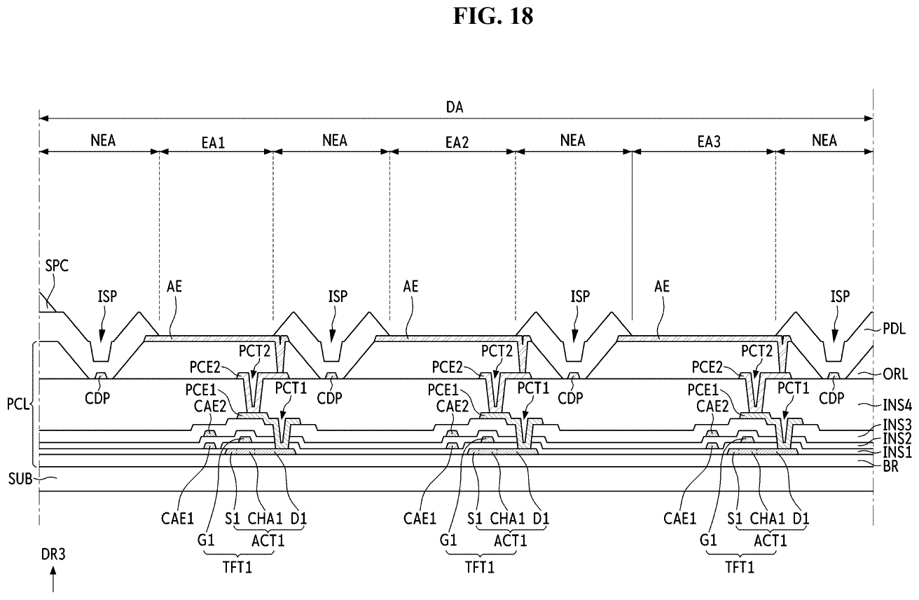

FIGS. 15 through 20 are cross-sectional views illustrating a method of manufacturing a display device according to an embodiment. For example, FIGS. 15 through 20 sequentially show manufacturing operations for forming separation structures ISP and a light emitting element layer LEL among manufacturing operations for manufacturing the display panel 100 according to the embodiment of FIGS. 6 and 7. In the description of the embodiment of FIGS. 15 through 20, a detailed description of a manufacturing process substantially identical or similar to the manufacturing process of the display panel 100 according to the embodiment of FIGS. 10 through 14 will be omitted.

Referring to FIG. 15, a circuit layer PCL may be formed on a substrate SUB. For example, circuit elements of subpixels including transistors TFT1 and conductive patterns CDP including wirings may be formed on the substrate SUB, and an organic layer ORL may be formed on the circuit elements and conductive patterns CDP.

The organic layer ORL may be opened to expose a portion of each of second connection electrodes PCE2 of the subpixels. For example, a via hole VH may be formed to penetrate the organic layer ORL on a portion of each of the second connection electrodes PCE2.

In an embodiment, the organic layer ORL may also be opened to include openings OPN at positions where the separation structures ISP are to be placed. In an embodiment, the via holes VH and the openings OPN of the organic layer ORL may be formed simultaneously by a process of patterning an organic insulating layer to form the organic layer ORL. Accordingly, the manufacturing efficiency of the display panel 100 can be increased. However, embodiments are not limited to this case. For example, the via holes VH and the openings OPN of the organic layer ORL may also be formed sequentially through respective mask processes.

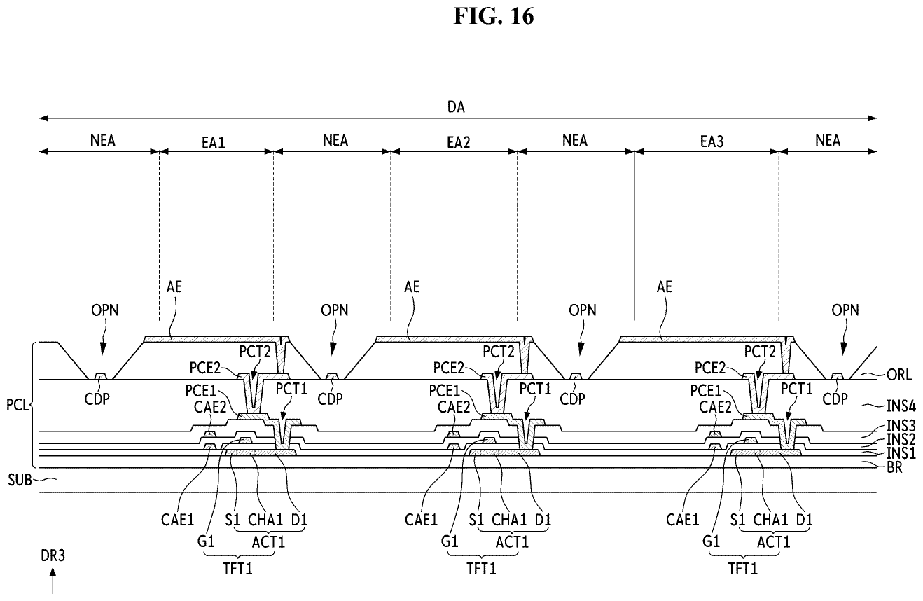

Referring to FIGS. 15 and 16, a first electrode AE of each of light emitting elements ED may be formed on the organic layer ORL. The first electrode AE of each of the light emitting elements ED may be formed in an emission area EA of each of the subpixels. The first electrode AE of each of the light emitting elements ED may fill a via hole VH penetrating the organic layer ORL and may be electrically connected to a second connection electrode PCE2 of each of the subpixels through the via hole VH.

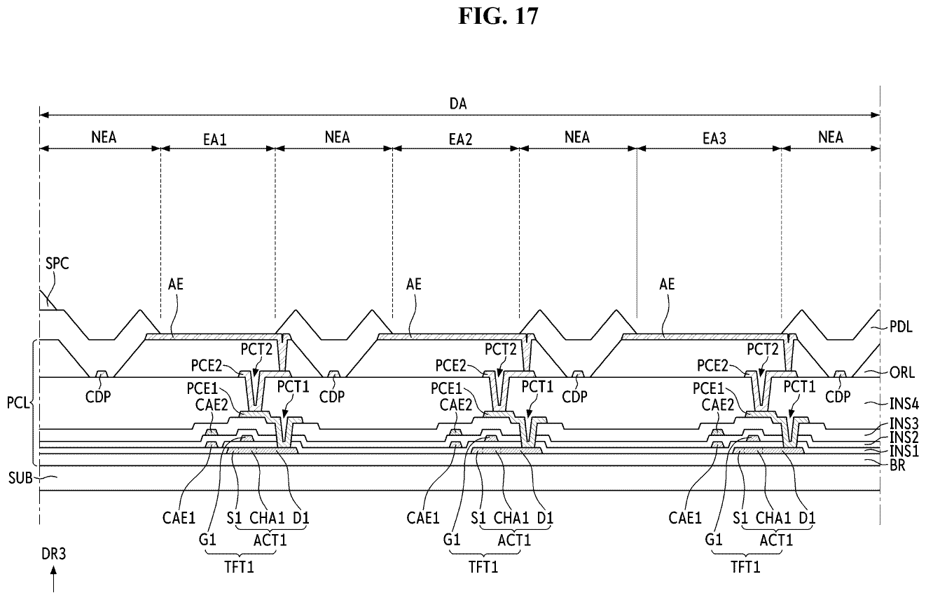

Referring to FIGS. 16 and 17, a pixel defining layer PDL and a spacer SPC may be formed on the organic layer ORL and the first electrodes AE of the light emitting elements ED. The pixel defining layer PDL may cover the openings OPN of the organic layer ORL. For example, a portion of the pixel defining layer PDL may fill the openings OPN of the organic layer ORL.

Referring to FIGS. 7 and 16 through 18, a separation structure ISP may be formed in a non-emission area NEA by forming a groove TRC in the pixel defining layer PDL in a portion covering each opening OPN of the organic layer ORL. For example, a groove TRC may be formed in the pixel defining layer PDL by using a mask which selectively exposes only a portion of the pixel defining layer PDL which covers each of the openings OPN of the organic layer ORL. Accordingly, the groove TRC of the pixel defining layer PDL may be formed to overlap each opening OPN of the organic layer ORL. In an embodiment, the groove TRC may be formed in the pixel defining layer PDL such that sidewalls of the groove TRC have a slope within a selected range by controlling a process method or process conditions. For example, the pixel defining layer PDL on each of the openings OPN of the organic layer ORL may be removed by a certain thickness by performing, e.g., a dry ashing or dry etching process. As a result, the groove TRC may be formed in the pixel defining layer PDL such that the sidewalls of the groove TRC have a slope of 70 to 90 degrees or have a reverse-tapered shape. When a display panel 100, which includes an additional groove TRC in addition to the separation structure ISP as in the embodiment of FIG. 9, is manufactured, the groove TRC of the separation structure ISP may be formed, and at the same time, an additional groove TRC may be further formed in the pixel defining layer PDL at a position spaced apart from the separation structure ISP.

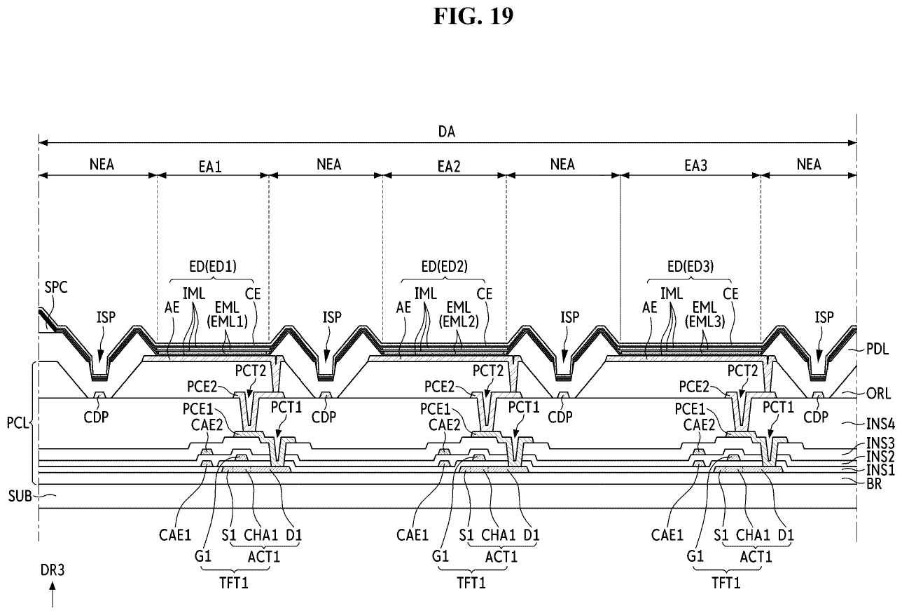

Referring to FIGS. 7 and 19, at least one intermediate layer IML, at least one light emitting layer EML, and a second electrode CE may be formed in each of the emission areas EA to form each of the light emitting elements ED. For example, a plurality of intermediate layers IML, a plurality of light emitting layers EML, and the second electrode CE may be formed in each of the emission areas EA to form the light emitting elements ED having a tandem structure.

In an embodiment, the light emitting layers EML may be individually formed in each emission area EA, and the intermediate layers IML and the second electrode CE may be formed as common layers over the entire display area DA. When the separation structures ISP are formed in the non-emission area NEA, the intermediate layers IML may be partially broken or separated by the separation structures ISP. In an embodiment, the second electrode CE may have a step corresponding to each of the separation structures ISP or may be partially broken by a groove TRC in at least one of the separation structures ISP.

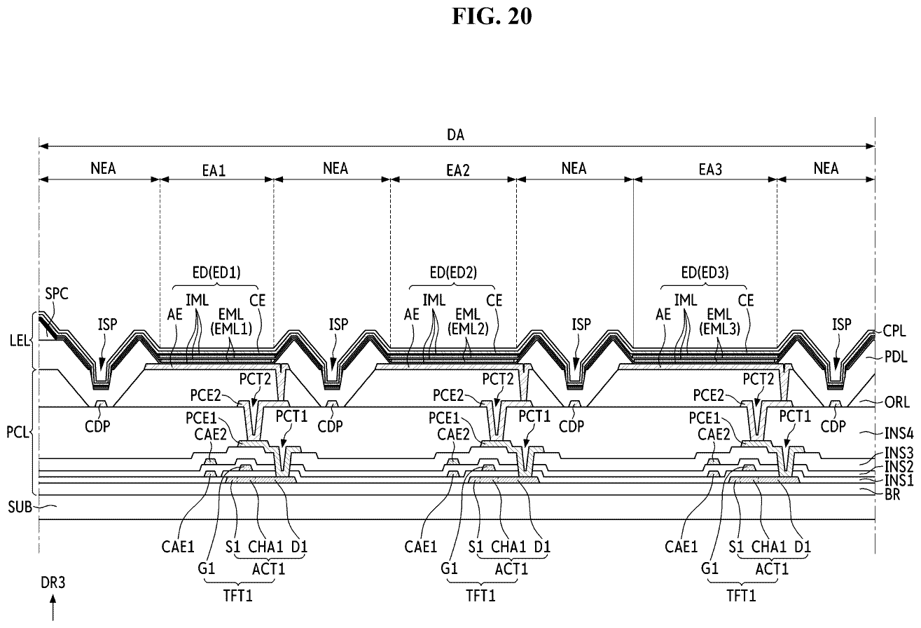

Referring to FIG. 20, a capping layer CPL may be formed on the light emitting elements ED. Accordingly, a display substrate including the circuit layer PCL and the light emitting element layer LEL may be formed.

Next, the light emitting element layer LEL may be encapsulated using the filler FIL and the encapsulation member ENC of FIG. 6 on the display substrate. Alternatively, the light emitting element layer LEL may be encapsulated by forming a thin-film encapsulation layer on the light emitting element layer LEL. Accordingly, the display panel 100 including the separation structures ISP according to the embodiment of FIGS. 6 and 7 may be manufactured.

As described above, a display device 10 and an electronic device 1 according to embodiments may include a display panel 100 including a separation structure ISP located between light emitting elements ED. The separation structure ISP according to the embodiments may include an opening OPN formed in one of an organic layer ORL and a pixel defining layer PDL, which are sequentially or continuously stacked, and a groove TRC formed in the other one of the organic layer ORL and the pixel defining layer PDL to overlap the opening OPN. In some embodiments, the groove TRC may be located in a center of the opening OPN and may completely overlap the opening OPN. Some embodiments provide a method of manufacturing the display device 10 including the separation structure ISP (e.g., the display panel 100 including the separation structure ISP).

According to the display device 10, the electronic device 1, and the method of manufacturing the display device 10 according to the embodiments, since an opening OPN is formed in one of the organic layer ORL and the pixel defining layer PDL, deterioration (e.g., deterioration due to sunlight, etc.) of the display device 10 and the electronic device 1 can be improved. At the same time, since a groove TRC having a relatively large lateral slope (e.g., a groove TRC whose sidewalls slope at an angle θ2 or θ2′ of 70 degrees or more) is formed in the other one of the organic layer ORL and the pixel defining layer PDL, leakage current (e.g., lateral leakage current between the light emitting elements ED due to intermediate layers IML) of the display device 10 and the electronic device 1 can be reduced or blocked. In addition, according to the display device 10, the electronic device 1, and the method of manufacturing the display device 10 according to the embodiments, the opening OPN and the groove TRC of each separation structure ISP are placed to overlap each other. Therefore, the separation structures ISP can be placed more efficiently in a non-emission area NEA. Accordingly, it is possible to improve the deterioration of the display device 10 and the electronic device 1 while improving the leakage current between the light emitting elements ED more effectively.

A display panel 100 according to at least one of the above-described embodiments or a display device 10 including the display panel 100 can be applied to various electronic devices 1. The electronic device 1 according to an embodiment includes the above-described display panel 100 or the display device 10, and may further include a module or device having another additional function in addition to the display panel 100 or the display device 10.

A display panel 100 according to at least one of the embodiments described above or a display device 10 including the display panel 100 can be applied to various electronic devices 1. An electronic device 1 according to an embodiment includes the display panel 100 or the display device 10 and may further include modules or devices having other additional functions, in addition to the display panel 100 or the display device 10.

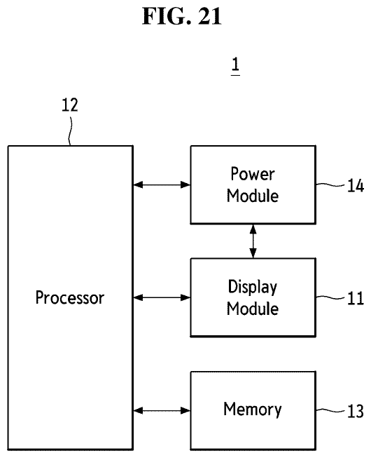

FIG. 21 is a block diagram of an electronic device 1 according to an embodiment.

Referring to FIG. 21, the electronic device 1 according to the embodiment may include a display module 11, a processor 12, a memory 13, and a power module 14.

The electronic device 1 may output various information in the form of images through the display module 11. For example, when the processor 12 executes an application stored in the memory 13, image information provided by the application may be provided to a user through the display module 11.

The display module 11 may include a display panel 100 for displaying an image. For example, the display module 11 may include a display panel 100 according to at least one of the embodiments described above.

The processor 12 may include at least one of a central processing unit (CPU), an application processor (AP), a graphic processing unit (GPU), a communication processor (CP), an image signal processor (ISP), and a controller. The processor 12 may be implemented by more than one processor and, collectively, two or more processors may be referred to as a processor.

The memory 13 may store data information necessary for the operation of the processor 12 or the display module 11. For example, the memory 13 may store an image data signal or an input control signal.

The processor 12 may control the display module 11 using information stored in the memory 13. The processor 12 may transmit an image data signal or an input control signal stored in the memory 13 to the display module 11. For example, when the processor 12 executes an application stored in the memory 13, an image data signal or an input control signal may be transmitted to the display module 11, and the display module 11 may process the received signal and output image information through a display screen.

The power module 14 may include a power supply module, such as a power adapter or a battery device, and a power conversion module which generates power necessary for the operation of the electronic device 1 by converting power supplied by the power supply module.

At least one of the elements of the electronic device 1 described above may be included in the display device 10 according to the above-described embodiments. In addition, some of individual modules functionally included in one module may be included in the display device 10, and other modules may be provided separately from the display device 10. For example, the display device 10 may include the display module 11, and the processor 12, the memory 13 and the power module 14 may be provided not in the display device 10, but in the form of other devices within the electronic device 1.

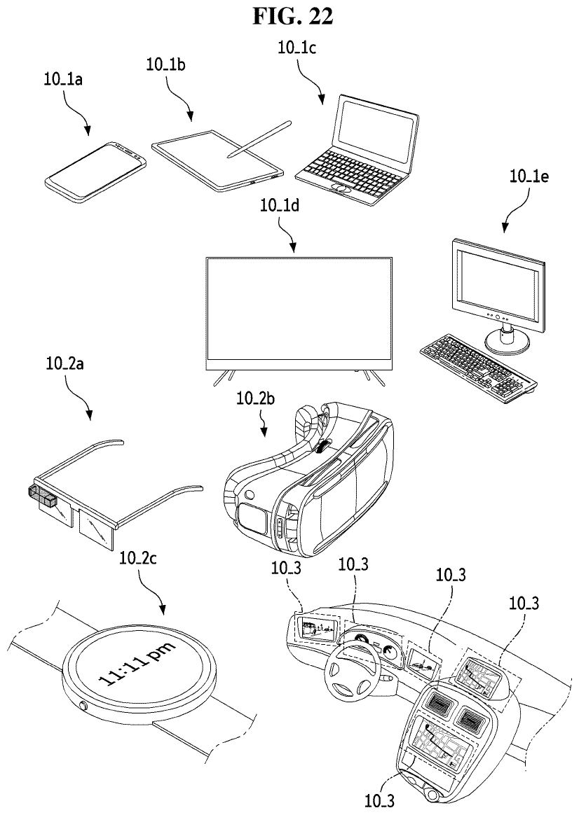

FIG. 22 is a schematic diagram of electronic devices according to various embodiments.

Referring to FIG. 22, various electronic devices (e.g., the electronic device 1 of FIG. 21) to which a display device 10 according to embodiments is applied may include not only image display electronic devices, such as a smartphone 10_1a, a tablet PC 10_1b, a laptop 10_1c, a television 10_1d and a desk monitor 10_1e, but also wearable electronic devices including a display module, such as smart glasses 10_2a, a head-mounted display 10_2b and a smart watch 10_2c, and vehicle electronic devices 10_3 including a display module, such as a center information display (CID) and a room mirror display placed on an instrument panel, a center fascia and a dashboard of a vehicle.

While the present disclosure has been described with reference to embodiments thereof, it will be apparent to those of ordinary skill in the art that various changes and modifications may be made thereto without departing from the scope and spirit of the present disclosure as set forth in the following claims.

What is claimed is:

1. A display device comprising:
a substrate;
a circuit layer located on the substrate and comprising transistors and an organic layer at least partially covering the transistors;
a light emitting element layer located on the organic layer and comprising light emitting elements located in emission areas and a pixel defining layer located in a non-emission area between the emission areas; and
a separation structure formed in the organic layer and the pixel defining layer in the non-emission area,
wherein the separation structure comprises:
an opening penetrating one of the organic layer and the pixel defining layer; and
a groove overlapping the opening and recessed into a surface of another one of the organic layer and the pixel defining layer.

2. The display device of claim 1, wherein a sidewall of the groove comprises an inclined surface and a slope of the inclined surface is greater than a slope of a sidewall of the opening.

3. The display device of claim 2, wherein the sidewall of the groove has a slope of 70 degrees or more.

4. The display device of claim 1, wherein each of the light emitting elements comprises a first electrode located in each of the emission areas, at least one light emitting layer and intermediate layers located on the first electrode, and a second electrode located on the at least one light emitting layer and the intermediate layers, the intermediate layers are located over a display area comprising the emission areas and the non-emission area, and at least one of the intermediate layers is broken or separated in an area where the groove is located.

5. The display device of claim 1, wherein in a width direction of the separation structure, a sidewall of the opening and a sidewall of the groove are located at positions spaced apart from each other.

6. The display device of claim 1, wherein the groove has a smaller width than the opening.

7. The display device of claim 6, wherein in the width direction of the separation structure, the groove is located in a center of the opening.

8. The display device of claim 1, wherein the emission areas comprise a first emission area and a second emission area extending in a first direction and adjacent to each other in a second direction, and the separation structure is located between the first emission area and the second emission area and extends in the first direction.

9. The display device of claim 1, further comprising a plurality of separation structures which comprise the separation structure, wherein the plurality of separation structures are distributed between the emission areas.

10. The display device of claim 9, further comprising spacers located on the pixel defining layer and spaced apart from the separation structures.

11. The display device of claim 1, wherein each of the organic layer and the pixel defining layer comprises an organic insulating material.

12. The display device of claim 1, wherein the circuit layer further comprises a conductive pattern located under the separation structure, and the conductive pattern is covered with one of the organic layer and the pixel defining layer.

13. The display device of claim 1, wherein the circuit layer further comprises a conductive pattern located under the organic layer and not overlapping the separation structure.

14. The display device of claim 13, wherein the pixel defining layer further comprises an additional groove recessed into a surface at a position overlapping the conductive pattern.

15. An electronic device comprising:
a display module comprising a display panel; and
a processor to transmit an image data signal to the display module,
wherein the display panel comprises:
a substrate;
a circuit layer located on the substrate and comprising transistors and an organic layer at least partially covering the transistors;
a light emitting element layer located on the organic layer and comprising light emitting elements located in emission areas and a pixel defining layer located in a non-emission area between the emission areas; and
a separation structure formed in the organic layer and the pixel defining layer in the non-emission area,
wherein the separation structure comprises:
an opening penetrating one of the organic layer and the pixel defining layer; and
a groove overlapping the opening and recessed into a surface of another one of the organic layer and the pixel defining layer.

16. The electronic device of claim 15, wherein a sidewall of the groove comprises an inclined surface and a slope of the inclined surface is greater than a slope of a sidewall of the opening.

17. The electronic device of claim 15, wherein in a width direction of the separation structure, a sidewall of the opening and a sidewall of the groove are located at positions spaced apart from each other.

18. A method of manufacturing a display device, the method comprising:
sequentially forming transistors and an organic layer, which at least partially covers the transistors, on a substrate;
forming first electrodes of light emitting elements on the organic layer;
forming a pixel defining layer, which defines emission areas where the first electrodes of the light emitting elements are exposed and is located in a non-emission area surrounding the emission areas, on the organic layer; and
forming light emitting layers, intermediate layers and a second electrode of the light emitting elements on the first electrodes of the light emitting elements and the pixel defining layer,
wherein an opening is formed in one of the organic layer and the pixel defining layer in the non-emission area and a groove is formed in another one of the organic layer and the pixel defining layer to overlap the opening, before the forming of the light emitting layers, the intermediate layers and the second electrode.

19. The method of claim 18, wherein the intermediate layers and the second electrode are formed over the entire display area comprising the emission areas and the non-emission area.

20. The method of claim 19, wherein the groove is formed to comprise a sidewall and a slope of the sidewall of the groove is greater than a slope of a sidewall of the opening, and at least one of the intermediate layers is broken or separated in an area where the groove is located.
